(19) United States
(12) Patent Application Publication
(10) Pub. No.: US 2026/0182175 A1
(43) Pub. Date: Jun. 25, 2026

(54) Display Substrate and Display Apparatus

(71) Applicant: BOE Technology Group Co., Ltd., Beijing (CN)

(72) Inventors: Hao ZHANG, Beijing (CN); Chunyan XIE, Beijing (CN)

(21) Appl. No.: 18/841,690

(22) PCT Filed: Sep. 26, 2023
(86) PCT No.: PCT/CN2023/121639

§ 371 Date: Aug. 27, 2024

(51) Int. Cl. H10K 59/131; H10K 59/121; H10K 59/122

(52) U.S. Cl. CPC H10K 59/131; H10K 59/1213; H10K 59/122

(57) ABSTRACT

The display substrate includes a base substrate and a plurality of sub-pixels (Pxij), a drive circuit layer, and a pixel definition layer disposed on the base substrate. In a direction perpendicular to a plane on which the display substrate is located, the drive circuit layer is located between the base substrate and the pixel definition layer. A plurality of pixel openings (80) are formed in the pixel definition layer. Each sub-pixel Pxij includes at least one pixel opening (80). The drive circuit layer may include a plurality of conductive layers. There is an overlapping area where an orthographic projection of a pixel opening (80) of at least one sub-pixel (Pxij) on the base substrate is overlapped with an orthographic projection of at least part of signal lines in the at least one conductive layer on the base substrate.

### CROSS-REFERENCE TO RELATED APPLICATIONS

The present application is a U.S. National Phase Entry of International Application PCT/CN2023/121639 having an international filing date of Sep. 26, 2023, and entire content of which is hereby incorporated by reference.

### TECHNICAL FIELD

The present disclosure relates to, but is not limited to, the field of display technologies, and particularly to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With continuous development of display technologies, a display apparatus in which an OLED or a QLED is used as a light emitting device and a Thin Film Transistor (TFT) is used for signal control has become a mainstream product in the field of display at present.

### SUMMARY

The following is a summary of subject matters described herein in detail. This summary is not intended to limit the protection scope of claims.

In a first aspect, the embodiment of the present disclosure provides a display substrate including a base substrate and a plurality of sub-pixels, a drive circuit layer and a pixel definition layer disposed on the base substrate, wherein the drive circuit layer is located between the base substrate and the pixel definition layer in a direction perpendicular to a plane on which the display substrate is located, wherein a plurality of pixel openings are formed in the pixel definition layer, each sub-pixel including at least one pixel opening, and the drive circuit layer includes a plurality of conductive layers;
there are overlapping areas between an orthographic projection of a pixel opening of at least one sub-pixel on the base substrate and orthographic projections of at least part of signal lines in at least one conductive layer on the base substrate; in the at least one sub-pixel, an overlapping area corresponding to one sub-pixel is symmetrical with respect to an orthographic projection of at least one midline of a pixel opening of the one sub-pixel on the base substrate.

In an exemplary implementation, at least part of the conductive layers include a conductive layer nearest to the pixel definition layer in the drive circuit layer in the direction perpendicular to the plane on which the display substrate is located.

In an exemplary implementation, the conductive layer nearest to the pixel definition layer in the drive circuit layer includes first power supply lines, the plurality of sub-pixels including multiple types of sub-pixels, and the multiple types of sub-pixels including a first sub-image, a second sub-pixel and a third sub-pixel;
both an area of an overlapping area where an orthographic projection of a pixel opening of the first sub-pixel on the base substrate is overlapped with an orthographic projection of a first power supply line on the base substrate and an area of an orthographic projection of an overlapping area where a pixel opening of the second sub-pixel on the base substrate is overlapped with the orthographic projection of the first power supply line on the base substrate are greater than an area of an overlapping area where an orthographic projection of a pixel opening of the third sub-pixel on the base substrate is overlapped with the orthographic projection of the first power supply line on the base substrate.

In an exemplary implementation, the conductive layer nearest to the pixel definition layer in the drive circuit layer further includes data signal lines, wherein there are overlapping areas where the orthographic projection of the pixel opening of the second sub-pixel on the base substrate is overlapped with orthographic projections of two first power supply lines and one data signal line adjacent to the pixel opening of the second sub-pixel on the base substrate, and in directions parallel to the plane on which the display substrate is located, the first power supply lines and the data signal lines extend in a second direction, and the two first power supply lines are respectively located on both sides of the one data signal line in a first direction, wherein the first direction intersects with the second direction.

In an exemplary implementation, there are two first overlapping areas where orthographic projections of the adjacent two first power supply lines on the base substrate are overlapped with an orthographic projection of a pixel opening of a corresponding second sub-pixel on the base substrate, and there is one second overlapping area where an orthographic projection of the one data signal line on the base substrate is overlapped with the orthographic projection of the pixel opening of the corresponding second sub-pixel on the base substrate, wherein in the first direction, the two first overlapping areas are located on both sides of the one second overlapping area, and the two first overlapping areas are symmetrical with respect to the one second overlapping area.

In an exemplary implementation, the conductive layer nearest to the pixel definition layer in the drive circuit layer is a second source drain metal layer, there is a first overlapping area where the orthographic projection of the pixel opening of the first sub-pixel on the base substrate is overlapped with orthographic projections of at least part of signal lines in the second source drain metal layer on the base substrate, there is a second overlapping area where the orthographic projection of the pixel opening of the second sub-pixel on the base substrate is overlapped with the orthographic projections of at least part of signal lines in the second source drain metal layer on the base substrate, and there is a third overlapping area where the orthographic projection of the pixel opening of the third sub-pixel on the base substrate is overlapped with the orthographic projections of at least part of signal lines in the second source drain metal layer on the base substrate, wherein areas of both the first overlapping area and the second overlapping area are greater than an area of the third overlapping area.

In an exemplary implementation, an orthographic projection of the first overlapping area on the base substrate is symmetrical with respect to an orthographic projection of a midline of the pixel opening of the first sub-pixel extending in at least one of the first direction and the second direction on the base substrate; an orthographic projection of the second overlapping area on the base substrate is symmetrical with respect to an orthographic projection of a midline of the pixel opening of the second sub-pixel extending in at least one of the first direction and the second direction on the base substrate; an orthographic projection of the third overlapping area on the base substrate is symmetrical with respect to an orthographic projection of a midline of the pixel opening of the third sub-pixel extending in at least one of the first direction and the second direction on the base substrate.

In an exemplary implementation, the orthographic projection of the pixel opening of the first sub-pixel on the base substrate is located within a range of the orthographic projection of the first power supply line on the base substrate.

In an exemplary implementation, an area of the pixel opening of the third sub-pixel is greater than an area of the pixel opening of the first sub-pixel, and is smaller than an area of the pixel opening of the second sub-pixel.

In an exemplary implementation, the first sub-pixel is a sub-pixel emitting red light, the second sub-pixel is a sub-pixel emitting blue light, and the third sub-pixel is a sub-pixel emitting green light.

In an exemplary implementation, the display substrate further includes an anode conductive layer located between the drive circuit layer and the pixel definition layer in the direction perpendicular to the plane on which the display substrate is located, wherein the anode conductive layer includes a plurality of anodes, an anode includes an anode main body portion, and each sub-pixel including at least one anode;
orthographic projections of pixel openings of the plurality of sub-pixels on the base substrate are respectively located within ranges of orthographic projections of the plurality of anodes on the base substrate, and there is an overlapping area where an orthographic projection of an anode main body portion of at least one sub-pixel on the base substrate is overlapped with the orthographic projections of the at least part of signal lines in the at least one conductive layer on the base substrate; among the at least one sub-pixel, an overlapping area corresponding to one sub-pixel is symmetrical with respect to an orthographic projection of at least one midline of an anode main body portion of the one sub-pixel on the base substrate.

In an exemplary implementation, the drive circuit layer includes a plurality of pixel drive circuits, at least part of the sub-pixels include the pixel drive circuits, and at least part of the pixel circuits include: at least one of first type transistor, at least one of second type transistor; the drive circuit layer includes at least a first semiconductor layer, a first conductive layer, a second conductive layer, a second semiconductor layer, and a third conductive layer sequentially disposed on the base substrate, wherein:
the first semiconductor layer includes at least: active layers of the first type transistor in the pixel drive circuits; the first conductive layer includes at least: gate electrodes of the first type transistor; the second conductive layer includes at least: a bottom gate of the second type transistor; the second semiconductor layer includes at least: an active layer of the second type transistor; the third conductive layer includes at least: a top gate of the second type transistor.

In an exemplary implementation, the first type transistor include at least a first transistor to a seventh transistor, a ninth transistor, and the second type transistor includes at least a eighth transistor;
in directions parallel to the plane on which the display substrate is located, in the first direction, a fourth transistor and a fifth transistor are located on a same side of a third transistor, a second transistor, a sixth transistor and a seventh transistor are located on the other side of the third transistor, and the eighth transistor is located between the second transistor and the fourth transistor; in the second direction, the fourth transistor and the fifth transistor are respectively located on both sides of the third transistor, the fifth transistor to the seventh transistor and the ninth transistor are located on a same side of the third transistor, the first transistor, the second transistor, the fourth transistor and the eighth transistor are located on a same side of the third transistor, and the first direction intersects with the second direction.

In an exemplary implementation, the pixel drive circuits of the plurality of sub-pixels are arranged in an array, and in a same column of pixel drive circuits of the sub-pixels, in the first direction, a first transistor in an i-th row of sub-pixels is located between a seventh transistor and a ninth transistor in an i-1-th row of sub-pixels, where i=2, 3, . . . , M+1, and M is an integer greater than or equal to 1.

In an exemplary implementation, the first conductive layer further includes a first scan signal line extending in the first direction, a first scan signal line located on the i-th row being electrically connected with the first transistor located on the i-th row, a seventh transistor and a ninth transistor located on the i-1-th row.

In an exemplary implementation, the first type transistor is a low temperature polysilicon transistor, and the second type transistor is an oxide transistor.

In an exemplary implementation, the drive circuit layer further includes a fourth conductive layer on a side of the third conductive layer away from the base substrate in the direction perpendicular to the plane on which the display substrate located, the fourth conductive layer including a plurality of second initial signal lines, a plurality of rows of second initial signal connection lines;
the pixel drive circuits of the plurality of sub-pixels are formed in a plurality of rows, the plurality of second initial signal lines are respectively electrically connected with the plurality of rows of the pixel drive circuits, and in directions parallel to the plane on which the display substrate is located, the plurality of second initial signal lines extend in a first direction and are arranged at intervals in a second direction, wherein the first direction intersects with the second direction;
each row of the second initial signal connection lines includes a plurality of the second initial signal connection lines extending in the second direction and arranged at intervals in the first direction, and in the second direction, each row of the second initial signal connection lines is located between two adjacent second initial signal lines, and both ends of the plurality of the second initial signal connection lines in each row of the second initial signal connection lines are respectively connected with the two adjacent second initial signal lines.

In an exemplary implementation, the drive circuit layer further includes a fifth conductive layer on a side of the fourth conductive layer away from the base substrate in the direction perpendicular to the plane on which the display substrate located, the fifth conductive layer including a plurality of second power supply lines, the second conductive layer further including a plurality of second power supply connection lines;
in directions parallel to the plane on which the display substrate located, the plurality of second power supply lines extend in the second direction and are arranged at intervals in the first direction, the plurality of second power supply connection lines extend in the first direction and are arranged at intervals in the second direction, and the plurality of second power supply lines and the plurality of second power supply connection lines are electrically connected through vias to form a grid-like structure.

In an exemplary implementation, in directions parallel to the plane on which the display substrate is located, the display substrate includes a first display region, a second display region and a connection region, the first display region and the second display region are connected through the connection region, the second display region at least partially surrounds the first display region, and the pixel drive circuits of the plurality of sub-pixels are located in the first display region and the second display region and are formed in a plurality of columns;
the third conductive layer further includes a plurality of second data signal connection lines, and the fifth conductive layer further includes a plurality of first data signal lines and a plurality of second data signal lines; the plurality of first data signal lines are respectively electrically connected with a plurality of columns of pixel drive circuits located in the first display region, and the plurality of second data signal lines are electrically connected with a plurality of columns of pixel drive circuits located in the second display region; the plurality of second data signal connection lines are located in the second display region, and are respectively electrically connected with the plurality of columns of pixel drive circuits located in the second display region.

In an exemplary implementation, the plurality of sub-pixels form a plurality of pixel units, the plurality of pixel units are arranged in an array, a pixel unit includes at least three adjacent sub-pixels, a second power supply line and a second initial signal connection line are disposed between two adjacent columns of pixel units, and a second power supply connection line and a second data signal connection line are located between two adjacent rows of pixel units.

In a second aspect, an embodiment of the present disclosure provides a display substrate including a first display region, a second display region, a bonding region and a connection region, wherein the first display region is connected with the second display region through the connection region, the second display region at least partially surrounds the first display region, and the bonding region is located on a side of the first display region in a direction parallel to a plane on which the display substrate is located;
the second display region is provided with a plurality of second data signal lines and a plurality of second data signal connection lines; one ends of the plurality of second data signal connection lines are respectively electrically connected with the plurality of second data signal lines, and the other ends are electrically connected with elements disposed in the bonding region.

In an exemplary implementation, the second display region is provided with a plurality of pixel units, the plurality of pixel units forming a plurality of second pixel unit rows and a plurality of second pixel unit columns, the plurality of second pixel unit columns being arranged sequentially in a direction from the first display region to the second display region, and distances between two adjacent second pixel unit rows are sequentially increased from a first second pixel unit column to a last second pixel unit column.

In an exemplary implementation, the first display region has a shape of a circular, and the second display region has a shape of a ribbon that at least partially surrounds the first display region.

In an exemplary implementation, the bonding region and the connection are located on two opposite sides of the first display region in a direction parallel to the plane on which the display substrate is located, and the elements disposed in the bonding region includes a driver chip, one ends of the plurality of second data signal connection lines being electrically connected with the driver chip.

In an exemplary implementation, the display substrate further includes a first outer bezel, wherein the first outer bezel is disposed on the periphery of the first display region, the first outer bezel including the connection region and the bonding region, the first outer bezel being provided with a plurality of second data signal adapter lines, the second data signal adapter lines and the second data signal connection lines being located in different conductive layers;
the second data signal connection lines extend from the second display region to the connection region, the plurality of second data signal adapter lines extend from the connection region along the first outer bezel to the bonding region, one ends being electrically connected with the plurality of second data signal connection lines located in the connection region, and the other ends being electrically connected with the driver chip.

In an exemplary implementation, the display substrate further includes a second outer bezel region and a second inner bezel region, wherein the second inner bezel region and the second outer bezel region are located on both sides of the second display region in a direction from the first display region to the second display region.

In an exemplary implementation, the second inner bezel region is connected to the first outer bezel region through the connection region, and the first outer bezel region and the second inner bezel region are provided with a second power supply signal supply line, wherein the second power supply signal supply line is electrically connected to the driver chip, and extends to the second inner bezel region via the first outer bezel region.

In an exemplary implementation, the display substrate further includes a cathode layer, the second display region includes second power supply connection lines electrically connected with a second power supply signal supply line in the second inner bezel region, and the second outer bezel region includes a second power supply lap line overlapped with the cathode layer and the second power supply connection lines, wherein the second power supply lap line is electrically connected with the second power supply connection lines and the cathode layer through vias.

In an exemplary implementation, the second power supply signal supply line located in the first outer bezel region is overlapped with the cathode layer and is electrically connected with the cathode layer through a via.

In an exemplary implementation, in a direction from the second display region to the second inner bezel region, the second inner bezel region sequentially includes: a first type gate drive circuit and a first type drive signal line, an initial signal line, a first power supply signal supply line, and a second power supply signal supply line electrically connected with the first type gate drive circuit;
in a direction from the second display region to the second outer bezel region, the second outer bezel region sequentially includes: a second type gate drive circuit and a second type drive signal line and a second power supply lap line electrically connected with the second type gate drive circuit, wherein the second type drive signal line is electrically connected with the driver chip via the second outer bezel region, the second inner bezel region, and the first outer bezel region.

In an exemplary implementation, the connection region is provided with an initial signal adapter electrode disposed in a different layer from the initial signal line, a first power supply adapter electrode disposed in a different layer from the first power supply signal supply line, a second power supply adapter electrode disposed in a different layer from or in a same layer as the second power supply signal supply line, and a drive signal adapter electrode disposed in a different layer from the first type drive signal line;
in a direction from the first display region to the first outer bezel region, the first outer bezel region sequentially includes: a first power supply signal supply line, an initial signal line, a first type drive signal line, and a second power supply signal supply line;
the first power supply signal supply line located in the first outer bezel region is electrically connected with the first power supply signal supply line located in the second inner bezel region through the first power supply adapter electrode; the initial signal line located in the first outer bezel region is electrically connected with the initial signal line located in the second inner bezel region through the initial signal adapter electrode; the first type drive signal line located in the first outer bezel region is electrically connected with the first type drive signal line through the drive signal adapter electrode; and the second power supply signal supply line located in the first outer bezel region is electrically connected with the second power supply signal supply line located in the second inner bezel region through the second power supply adapter electrode.

In an exemplary implementation, the second display region further includes a plurality of second type scan signal lines, an output terminal of each second type gate drive circuit is electrically connected with two corresponding second type scan signal lines, and each second type scan signal line is electrically connected with a plurality of sub-pixels in one of second pixel unit rows.

In an exemplary implementation, sizes of each second type gate drive circuit and two adjacent second pixel unit rows of the each second type gate drive circuit in an extension direction of the second outer bezel are consistent;
or, each second type gate drive circuit is divided into two parts of circuits connected with each other, and in the extension direction of the second outer bezel region, the two parts of circuits and the two adjacent second pixel unit rows are consistent, respectively;
or, the two adjacent second pixel unit rows are served as one unit module, and in the extension direction of the second outer bezel region, a distance between adjacent two unit modules is greater than a distance between two second pixel units in a same unit module, and sizes of each second type gate drive circuit and one adjacent unit module of the each second type gate drive circuit are consistent in the extension direction of the second outer bezel region.

In an exemplary implementation, in the direction from the first display region to the first outer bezel region, the first outer bezel region sequentially includes: a second power supply signal supply line, a first power supply signal supply line, an initial signal line, a gate drive circuit and a drive signal line connected thereto.

In a third aspect, an embodiment of the present disclosure also provides a display apparatus including the display substrate described in any of the above embodiments.

Other aspects of the present disclosure may be comprehended after the drawings and the detailed descriptions are read and understood.

### BRIEF DESCRIPTION OF DRAWINGS

Accompanying drawings are used for providing further understanding of technical solutions of embodiments of the present disclosure, constitute a portion of the specification, and are used for explaining the technical solutions of the present disclosure together with embodiments of the present disclosure, but do not constitute limitations on the technical solutions of the present disclosure. Shapes and sizes of each component in the drawings do not reflect actual scales, but are only intended to schematically illustrate contents of the present disclosure.

FIG. 1 is a schematic diagram of a structure of a display apparatus.

FIG. 2 is a schematic diagram of a planar structure of a display substrate.

FIG. 3 is a schematic diagram of a sectional structure of a display area in a display substrate.

FIG. 4 is an equivalent circuit diagram of a pixel drive circuit.

FIG. 5 is a working timing diagram of a pixel drive circuit.

FIG. 6 shows a schematic diagram of a structure of a display substrate according to an exemplary embodiment of the present disclosure.

FIG. 7 shows a schematic diagram of a planar structure of a display substrate according to an exemplary embodiment of the present disclosure.

FIG. 8 shows an equivalent circuit diagram of a pixel drive circuit according to an exemplary embodiment of the present disclosure.

FIG. 9a shows a schematic diagram of a structure of a display substrate according to an exemplary embodiment of the present disclosure.

FIG. 9b shows a schematic diagram of a structure of a display substrate according to an exemplary embodiment of the present disclosure.

FIG. 9c shows a schematic partial enlarged view of M1 position in FIG. 9a.

FIG. 9d shows a schematic diagram of a structure of a display substrate according to an exemplary embodiment of the present disclosure.

FIG. 9e shows a schematic partial enlarged view of M1 position in FIG. 9a.

FIG. 9f shows a schematic partial enlarged view of M2 position in FIG. 9a.

FIG. 9g shows a schematic partial enlarged view of M2 position in FIG. 9a.

FIG. 9 h shows a schematic partial enlarged view of M2 position in FIG. 9a.

FIG. 9i is a schematic diagram of a structure of an ERD watch assembled using the display substrate shown in FIG. 9a;

FIG. 10 shows a schematic diagram of a display substrate according to an exemplary embodiment of the present disclosure after a pattern of a first semiconductor layer is formed.

FIG. 11a shows a schematic diagram of a display substrate according to an exemplary embodiment of the present disclosure after a pattern of a first conductive layer is formed.

FIG. 11b shows a schematic diagram of a first conductive layer in a display substrate according to an exemplary embodiment of the present disclosure.

FIG. 12a shows a schematic diagram of a display substrate according to an exemplary embodiment of the present disclosure after a pattern of a second conductive layer is formed.

FIG. 12b shows a schematic diagram of a second conductive layer in a display substrate according to an exemplary embodiment of the present disclosure.

FIG. 13a shows a schematic diagram of a display substrate according to an exemplary embodiment of the present disclosure after a pattern of a second semiconductor layer is formed.

FIG. 13b shows a schematic diagram of a second semiconductor layer in a display substrate according to an exemplary embodiment of the present disclosure.

FIG. 14a shows a schematic diagram of a display substrate according to an exemplary embodiment of the present disclosure after a pattern of a third conductive layer is formed.

FIG. 14b shows a schematic diagram of a third conductive layer in a display substrate according to an exemplary embodiment of the present disclosure.

FIG. 15 shows a schematic diagram of a display substrate according to an exemplary embodiment of the present disclosure after a pattern of a sixth insulation layer is formed.

FIG. 16a shows a schematic diagram of a display substrate according to an exemplary embodiment of the present disclosure after a pattern of a fourth conductive layer is formed.

FIG. 16b shows a schematic diagram of a fourth conductive layer in a display substrate according to an exemplary embodiment of the present disclosure.

FIG. 17 shows a schematic diagram after a pattern of a first planarization layer is formed according to an exemplary embodiment of the present disclosure.

FIG. 18a shows a schematic diagram of a display substrate according to an exemplary embodiment of the present disclosure after a pattern of a fifth conductive layer is formed.

FIG. 18b shows a schematic diagram of a fifth conductive layer in a display substrate according to an exemplary embodiment of the present disclosure.

FIG. 19 shows a schematic diagram of a display substrate according to an exemplary embodiment of the present disclosure after a pattern of a second planarization layer is formed.

FIG. 20a shows a schematic diagram of a display substrate according to an exemplary embodiment of the present disclosure after a pattern of an anode conductive layer is formed.

FIG. 20b shows a schematic diagram of an anode conductive layer in a display substrate according to an exemplary embodiment of the present disclosure.

FIG. 21a is a schematic diagram of a display substrate according to an exemplary embodiment of the present disclosure after a pattern of a pixel definition layer is formed.

FIG. 21b shows a schematic diagram of a pattern of a pixel definition layer in a display substrate according to an exemplary embodiment of the present disclosure.

### DETAILED DESCRIPTION

Embodiments of the present disclosure will be described in detail hereinafter with reference to the drawings. Implementation modes may be implemented in a plurality of different forms. Those of ordinary skills in the art can easily understand such a fact that implementation modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a thickness and a pitch of each film layer, and a width and a pitch of each signal line may be adjusted according to an actual situation. The drawings described in the present disclosure are only schematic diagrams of structures, and one implementation of the present disclosure is not limited to shapes or numerical values or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction which is used for describing each constituent element. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification. In an embodiment of the present disclosure, the gate electrode may be referred to as a control electrode.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In an embodiment of the present disclosure, “about” refers to a value that is not strictly limited, a value within a range of process and measurement error is allowed.

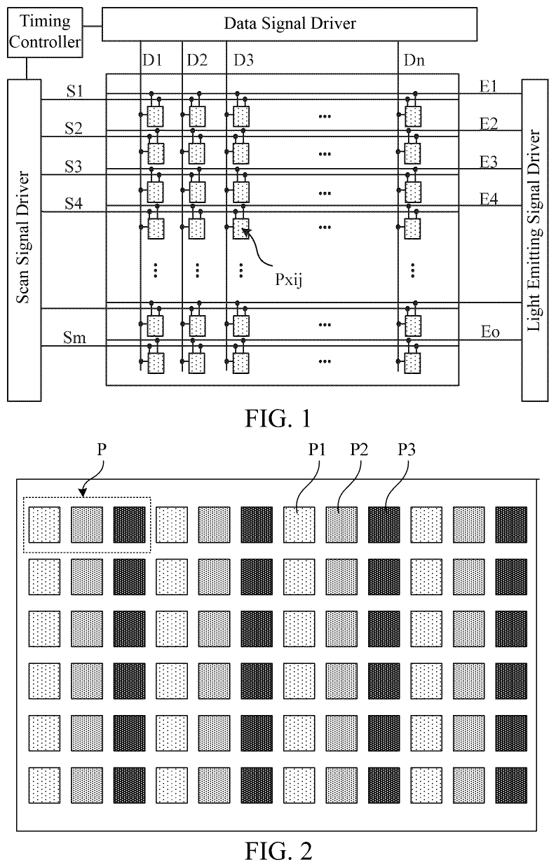

FIG. 1 is a schematic diagram of a structure of a display apparatus, the display substrate may include a timing controller, a data signal driver, a scan signal driver, a light emitting signal driver, and a pixel array. The timing controller is connected with the data signal driver, the scan signal driver, and the light emitting signal driver, respectively, the data signal driver is connected with a plurality of data signal lines (D1 to Dn) respectively, the scan signal driver is connected with a plurality of scan signal lines (S1 to Sm) respectively, and the light emitting signal driver is connected with a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting device connected to the circuit unit, and the circuit unit may include at least one scan signal line, at least one data signal line, at least one light emitting signal line, and a pixel drive circuit. In an exemplary implementation, the timing controller may provide a gray scale value and a control signal suitable for a specification of the data signal driver to the data signal driver, may provide a clock signal, and a scan start signal, etc., suitable for a specification of the scan signal driver to the scan signal driver, and may provide a clock signal, and an emission stop signal, etc., suitable for a specification of the light emitting signal driver to the light emitting signal driver. The data signal driver may generate data voltages to be provided to data signal lines D1, D2, D3, . . . , and Dn using the gray scale value and the control signal received from the timing controller. For example, the data signal driver may sample the gray scale value using a clock signal and apply a data voltage corresponding to the gray scale value to the data signal lines D1 to Dn by taking a pixel row as a unit, wherein n may be a natural number. The scan signal driver may generate scan signals to be provided to scan signal lines S1, S2, S3, . . . , and Sm by receiving a clock signal, a scan start signal, and the like from the timing controller. For example, the scan signal driver may sequentially provide scan signals with turning-on-level pulses to the scan signal lines S1 to Sm. For example, the scan signal driver may be constructed in a form of a shift register, and generate the scan signals in a mode of sequentially transmitting the scan start signal provided in a form of turning-on-level pulses to a next-stage circuit under controlling of the clock signal, wherein m may be a natural number. The light emitting signal driver may generate an emission signal to be provided to emitting signal lines E1, E2, E3, . . . , and Eo by receiving the clock signal, the transmission stop signal, and the like from the timing controller. For example, the light emitting signal driver may sequentially provide an emission signal with an off-level pulse to the light emitting signal lines E1 to Eo. For example, the light emitting signal driver may be constructed in a form of a shift register and generate an emission signal in a manner of sequentially transmitting an emission stop signal provided in a form of an off-level pulse to a next-stage circuit under control of the clock signal, wherein o may be a natural number.

FIG. 2 is a schematic diagram of a planar structure of a display substrate. As shown in FIG. 2, the display substrate may include a plurality of pixel units P arranged in a matrix, at least one of the plurality of pixel units P includes a first sub-pixel P1 emitting light of a first color, a second sub-pixel P2 emitting light of a second color, and a third sub-pixel P3 emitting light of a third color. The first sub-pixel P1, the second sub-pixel P2, and the third sub-pixel P3 each include a pixel drive circuit and a light emitting device. Pixel drive circuits in the first sub-pixel P1, the second sub-pixel P2, and the third sub-pixel P3 are connected with a scan signal line, a data signal line, and a light emitting signal line respectively. A pixel drive circuit is configured to receive a data voltage transmitted by the data signal line under control of the scan signal line and the light emitting signal line, and output a corresponding current to the light emitting device. Light emitting devices in the first sub-pixel P1, the second sub-pixel P2, and the third sub-pixel P3 are respectively connected with the pixel drive circuit of the sub-pixel in which the light emitting device is located, and the light emitting device is configured to emit light with a corresponding brightness in response to a current outputted by the pixel drive circuit of the sub-pixel in which the light emitting device is located.

In an exemplary implementation, a pixel unit P may include a red (R) sub-pixel, a green (G) sub-pixel, and a blue (B) sub-pixel. In an exemplary implementation, a sub-pixel in the pixel unit may be in a shape of a rectangle, a rhombus, a pentagon, or a hexagon. Three sub-pixels may be arranged side by side horizontally, side by side vertically, or in a manner like a Chinese character “ ”, which is not limited in the present disclosure.

FIG. 3 is a schematic diagram of a cross-sectional structure of a display substrate, which illustrates a structure of three sub-pixels of an OLED display substrate. As shown in FIG. 3, on a plane perpendicular to the display substrate, the display substrate may include a drive circuit layer 102 disposed on a base substrate 101, a light emitting structure layer 103 disposed on a side of the drive circuit layer 102 away from the base substrate 101, and an encapsulation layer 104 disposed on a side of the light emitting structure layer 103 away from the base substrate 101. In some possible implementations, the display substrate may include another film layer, such as a post spacer, which is not limited in the present disclosure.

In an exemplary implementation, the base substrate 101 may be a flexible substrate, or may be a rigid substrate. The drive circuit layer 102 of each sub-pixel may include a plurality of transistors and a storage capacitor constituting a pixel drive circuit. The light emitting structure layer 103 may include an anode 301 connected to a drain electrode of a driving transistor 210 through a via, an organic light emitting layer 302 connected to the anode 301, and a cathode 303 connected to the organic light emitting layer 302, which emits light of corresponding color under drive of the anode 301 and the cathode 303. The encapsulation layer 104 may include a first encapsulation layer 401, a second encapsulation layer 402, and a third encapsulation layer 403 that are stacked. The first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 so as to prevent external water vapor from entering the light emitting structure layer 103.

In an exemplary implementation, the organic emitting layer 302 may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) which are stacked. In an exemplary implementation, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

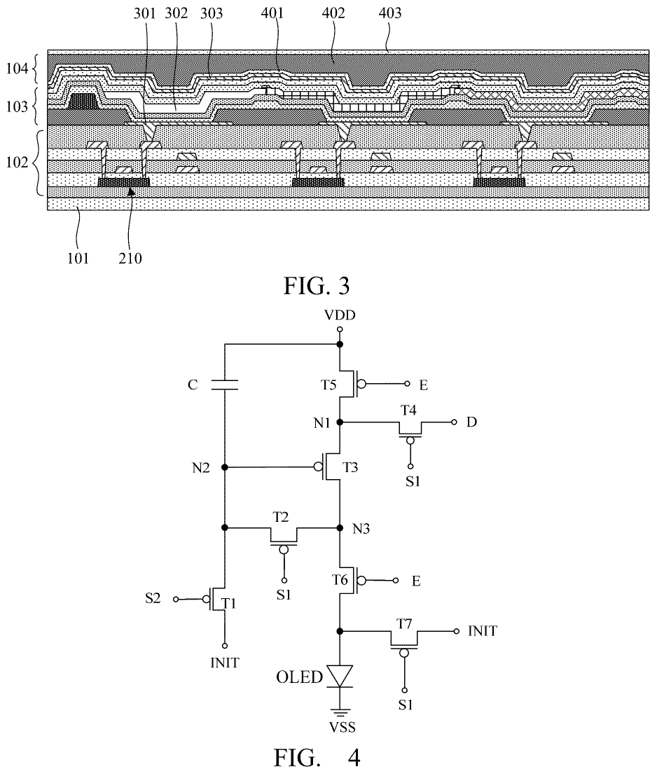

In an exemplary implementation, the pixel drive circuit may be of a structure of 3TIC, 4T1C, 5T1C, 5T2C, 6TIC, or 7T1C. FIG. 4 is an equivalent circuit diagram of a pixel drive circuit. As shown in FIG. 4, the pixel drive circuit may include seven transistors (a first transistor T1 to a seventh transistor T7) and one storage capacitor C, and the pixel drive circuit may be connected with seven signal lines (a data signal line D, a first scan signal line S1, a second scan signal line S2, a light emitting signal line E, an initial signal line INIT, a first power supply line VDD, and a second power supply line VSS).

In an exemplary implementation, the pixel drive circuit may include a first node N1, a second node N2, and a third node N3. The first node N1 is connected with a first electrode of the third transistor T3, a second electrode of the fourth transistor T4, and a second electrode of the fifth transistor T5 respectively. The second node N2 is connected with a second electrode of the first transistor T1, a first electrode of the second transistor T2, a control electrode of the third transistor T3, and a second terminal of the storage capacitor C respectively. The third node N3 is connected with a second electrode of the second transistor T2, a second electrode of the third transistor T3, and a first electrode of the sixth transistor T6 respectively.

In an exemplary implementation, a first end of the storage capacitor C is connected to the first power supply line VDD, and the second end of the storage capacitor C is connected to the second node N2, i.e., the second end of the storage capacitor C is connected to the control electrode of the third transistor T3.

The control electrode of the first transistor T1 is connected with the second scan signal line S2, the first electrode of the first transistor T1 is connected with the initial signal line INIT, and the second electrode of the first transistor is connected with the second node N2. When a scan signal with an on-level is applied to the second scan signal line S2, the first transistor T1 transmits an initialization voltage to the control electrode of the third transistor T3, so as to initialize a charge amount of the control electrode of the third transistor T3.

A control electrode of the second transistor T2 is connected with the first scan signal line S1, a first electrode of the second transistor T2 is connected with the second node N2, and a second electrode of the second transistor T2 is connected with the third node N3. When a scan signal with an on-level is applied to the first scan signal line S1, the second transistor T2 enables the control electrode of the third transistor T3 to be connected with the second electrode of the third transistor T3.

A control electrode of the third transistor T3 is connected with the second node N2, i.e., the control electrode of the third transistor T3 is connected with the second end of the storage capacitor C, a first electrode of the third transistor T3 is connected with the first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

A control electrode of the fourth transistor T4 is connected with the first scan signal line S1, a first electrode of the fourth transistor T4 is connected with the data signal line D, and a second electrode of the fourth transistor T4 is connected with the first node N1. The fourth transistor T4 may be referred to as a switching transistor, a scan transistor, etc., and the fourth transistor T4 enables a data voltage of the data signal line D to be input into the pixel drive circuit when a scan signal with an on-level is applied to the first scan signal line S1.

A control electrode of the fifth transistor T5 is connected with the light emitting signal line E, a first electrode of the fifth transistor T5 is connected with the first power supply line VDD, and a second electrode of the fifth transistor T5 is connected with the first node N1. A control electrode of the sixth transistor T6 is connected to the light emitting signal line E, the first electrode of the sixth transistor T6 is connected to the third node N3, and a second electrode of the sixth transistor T6 is connected to a first electrode of a light emitting device. The fifth transistor T5 and the sixth transistor T6 may be referred to as light emitting transistors. When a light emitting signal with an on-level is applied to the light emitting signal line E, the fifth transistor T5 and the sixth transistor T6 enable the light emitting device to emit light by forming a drive current path between the first power supply line VDD and the second power supply line VSS.

The control electrode of the seventh transistor T7 is connected with the first scan signal line S1, the first electrode of the seventh transistor T7 is connected with the initial signal line INIT, and the second electrode of the seventh transistor T7 is connected with the first electrode of the light emitting device. When a scan signal with an on-level is applied to the first scan signal line S1, the seventh transistor T7 transmits an initialization voltage to the first electrode of the light emitting device so as to initialize a charge amount accumulated in the first electrode of the light emitting device or release a charge amount accumulated in the first electrode of the light emitting device.

In an exemplary implementation, a second electrode of the light emitting device is connected to the second power supply line VSS, a signal of the second power supply line VSS is a low-level signal, and a signal of the first power supply line VDD is a high-level signal continuously provided. The first scan signal line S1 is a scan signal line in a pixel drive circuit in a current display row, and the second scan signal line S2 is a scan signal line in a pixel drive circuit in a previous display row, that is, for the n-th display row, the first scan signal line S1 is S(n), and the second scan signal line S2 is S(n-1). The second scan signal line S2 in the pixel drive circuit in the current display row and the first scan signal line S1 in the pixel drive circuit in the previous display row are the same signal line, such that signal lines of a display panel can be reduced, so as to achieve a narrow bezel of the display panel.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, the first scan signal line S1, the second scan signal line S2, the light emitting signal line E, and the initial signal line INIT extend along a horizontal direction, and the second power supply line VSS, the first power supply line VDD, and the data signal line D extend along a vertical direction.

In an exemplary implementation, the light emitting device may be an Organic Light Emitting Diode (OLED) including a first electrode (anode), an organic emitting layer, and a second electrode (cathode) that are stacked.

FIG. 5 is a working timing diagram of a pixel drive circuit. An exemplary implementation will be described below through a working process of the pixel drive circuit illustrated in FIG. 4. The pixel drive circuit in FIG. 4 includes seven transistors (a first transistor T1 to a seventh transistor T7), one storage capacitor C, and seven signal lines (a data signal line D, a first scan signal line S1, a second scan signal line S2, a light emitting signal line E, an initial signal line INIT, a first power supply line VDD, and a second power supply line VSS), wherein all of the seven transistors are P-type transistors.

In an exemplary implementation, the working process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is the low-level signal, so that the first transistor T1 is turned on, and a signal of the initial signal line INIT is provided to the second node N2 to initialize the storage capacitor C to clear an original data voltage in the storage capacitor. The signals of the first scan signal line S1 and the light emitting signal line E are the high-level signals, so that the second transistor T2, the fourth transistor T4, the fifth transistor T5, the sixth transistor T6, and the seventh transistor T7 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization and ensuring that the OLED does not emit light. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and the first electrode of the third transistor T3. The voltage of the second node N2 is Vdata−|Vth|, so the drive current of the third transistor T3 is as follows:

$$I = K * {( V gs - V th )}^{2} = K * {[ ( V dd - V d + \vert V th \vert ) - V th ]}^{2} = K * {[ ( V dd - V d ) ]}^{2}$$

Herein, I is a drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

With the advancement of display technology, flexible display devices are gradually developing from two-dimensional display to three-dimensional display. For example, for a wearable watch with a display, not only is the maximization of the front display pursued, but also the side display is required to be able to be displayed, pursuing a surround display perspective sensory effect. In addition, due to the unreasonable setting of the signal wirings in the display substrate, the display panel has a defect of a color cast with a large viewing angle, which affects the display effect to some extent.

An exemplary embodiment of the present disclosure provides a display substrate, which may include a base substrate and a plurality of sub-pixels disposed on the base substrate, a drive circuit layer, and a pixel definition layer, wherein in a direction perpendicular to a plane on which the display substrate is located, the drive circuit layer is located between the base substrate and the pixel definition layer, a plurality of pixel openings are formed in the pixel definition layer, each sub-pixel including at least one pixel opening, and the drive circuit layer may include a plurality of conductive layers;
there are overlapping areas between an orthographic projection of a pixel opening of at least one sub-pixel on the base substrate and orthographic projections of at least part of signal lines in the at least one conductive layer on the base substrate; in the at least one sub-pixel, an overlapping area corresponding to one sub-pixel is symmetrical with respect to an orthographic projection of at least one midline of a pixel opening of the one sub-pixel on the base substrate.

In a display substrate provided in an embodiment of the present disclosure, there are overlapping areas between an orthographic projection of a pixel opening of at least one sub-pixel in the display substrate on the base substrate and orthographic projections of at least part of signal lines in at least one conductive layer on the base substrate, and in the at least one sub-pixel, an overlapping area corresponding to one sub-pixel is symmetrical with respect to an orthographic projection of at least one midline of a pixel opening of the one sub-pixel on the base substrate, so that the technical problem of the color cast with the large viewing angle in the display substrate can be solved.

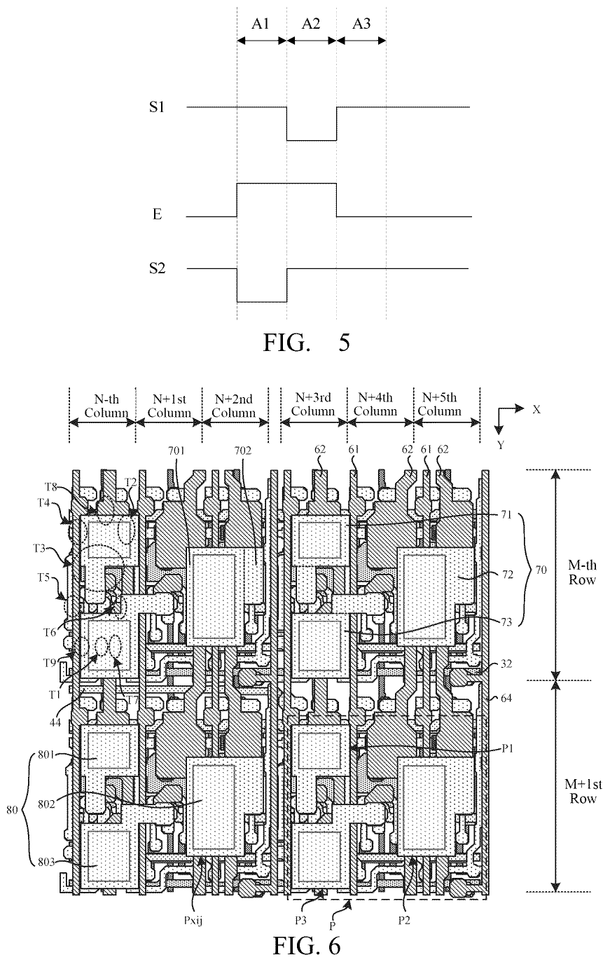

As shown in FIG. 6, a display substrate provided in an embodiment of the present disclosure may include a base substrate and a plurality of sub-pixels Pxij, a drive circuit layer and a pixel definition layer disposed on the base substrate. In a direction perpendicular to a plane on which the display substrate is located, the drive circuit layer is located between the base substrate and the pixel definition layer. A plurality of pixel openings 80 are formed in the pixel definition layer, each sub-pixel Pxij including at least one pixel opening 80, and the drive circuit layer may include a plurality of conductive layers;
there are overlapping areas between an orthographic projection of a pixel opening 80 of at least one sub-pixel Pxij on the base substrate and orthographic projections of at least part of signal lines in a at least one conductive layer on the base substrate, and in the at least one sub-pixel Pxij, an overlapping area corresponding to one sub-pixel Pxij is symmetrical with respect to an orthographic projection of at least one midline of a pixel opening 80 of the one sub-pixel on the base substrate.

In an exemplary implementation, at least part of the conductive layers include a conductive layer nearest to the pixel definition layer in the drive circuit layer in the direction perpendicular to the plane on which the display substrate is located.

In an exemplary implementation, as shown in FIG. 6, the conductive layer nearest to the pixel definition layer in the drive circuit layer may include first power supply lines 62, and the plurality of sub-pixels Pxij may include multiple types of sub-pixels, the multiple types of sub-pixels including a first sub-pixel P1, a second sub-pixel P2, and a third sub-pixel P3;
both an area of an overlapping area where an orthographic projection of a pixel opening 801 of the first sub-pixel P1 on the base substrate is overlapped with an orthographic projection of a first power supply line 62 on the base substrate and an area of an overlapping area where an orthographic projection of a pixel opening 802 of the second sub-pixel P2 on the base substrate is overlapped with the orthographic projection of the first power supply line 62 on the base substrate are greater than an area of an overlapping area where an orthographic projection of a pixel opening of the third sub-pixel P3 on the base substrate is overlapped with the orthographic projection of the first power supply line 62 on the base substrate.

In an exemplary implementation, areas of overlapping areas where pixel openings 80 of the different sub-pixels are overlapped with the first power supply line 62 are different, so that flatnesses of the conductive layer nearest to the pixel definition layer in the drive circuit layer at positions of corresponding pixel openings 80 can be improved, thereby improving the color cast.

In an exemplary implementation, as shown in FIG. 6, the conductive layer nearest to the pixel definition layer in the drive circuit layer further includes data signal lines 61, wherein there are overlapping areas where the orthographic projection of the pixel opening 802 of the second sub-pixel P2 on the base substrate is overlapped with orthographic projections of two first power supply lines 62 and one data signal line 61 adjacent to the pixel opening 802 of the second sub-pixel P2 on the base substrate, and in directions parallel to the plane on which the display substrate is located, the first power supply lines 62 and the data signal lines 61 extend in a second direction Y, and the two first power supply lines 62 are respectively located on both sides of the one data signal line 61 in a first direction X, wherein the first direction X intersects with the second direction Y.

In an exemplary implementation, there are overlapping areas where the orthographic projection of the pixel opening 802 of the second sub-pixel P2 on the base substrate is overlapped with orthographic projections of adjacent two first power supply lines 62 and one data signal line 61 on the base substrate, so that the flatness of the conductive layer nearest to the pixel definition layer in the drive circuit layer at positions of the pixel opening 802 of the second sub-pixel P2 can be improved.

In an exemplary implementation, as shown in FIG. 6, there are two first overlapping areas where orthographic projections of the adjacent two first power supply lines 62 on the base substrate are overlapped with an orthographic projection of a pixel opening 802 of a corresponding second sub-pixel P2 on the base substrate, and there is one second overlapping area where an orthographic projection of the one data signal line 61 on the base substrate is overlapped with the orthographic projection of the pixel opening 802 of the corresponding second sub-pixel P2 on the base substrate, wherein in the first direction X, the two first overlapping areas are located on both sides of the one second overlapping area, and the two first overlapping areas are symmetrical with respect to the one second overlapping area, so that the defect of the color cast with the large viewing angle of the second sub-pixel P2 can be improved.

In an exemplary implementation, as shown in FIG. 6, the conductive layer nearest to the pixel definition layer in the drive circuit layer is a second source drain metal layer, there is a first overlapping area where the orthographic projection of the pixel opening 801 of the first sub-pixel P1 on the base substrate is overlapped with orthographic projections of at least part of signal lines in the second source drain metal layer on the base substrate, there is a second overlapping area where the orthographic projection of the pixel opening 802 of the second sub-pixel P2 on the base substrate is overlapped with the orthographic projections of at least part of signal lines in the second source drain metal layer on the base substrate, and there is a third overlapping area where the orthographic projection of the pixel opening 803 of the third sub-pixel P3 on the base substrate is overlapped with the orthographic projections of at least part of signal lines in the second source drain metal layer on the base substrate, wherein areas of both the first overlapping area and the second overlapping area are greater than an area of the third overlapping area.

In an exemplary implementation, an orthographic projection of the first overlapping area on the base substrate may be symmetrical with respect to an orthographic projection of a midline of the pixel opening 801 of the first sub-pixel P1 extending in at least one of the first direction X and the second direction Y on the base substrate; an orthographic projection of the second overlapping area on the base substrate may be symmetrical with respect to an orthographic projection of a midline of the pixel opening 802 of the second sub-pixel P2 extending in at least one of the first direction X and the second direction Y on the base substrate; an orthographic projection of the third overlapping area on the base substrate may be symmetrical with respect to an orthographic projection of a midline of the pixel opening 803 of the third sub-pixel P3 extending in at least one of the first direction X and the second direction Y on the base substrate. In an exemplary implementation, an area where an orthographic projection of a pixel opening on the base substrate is overlapped with an orthographic projection of the second source drain metal layer on the base substrate is symmetrical with respect to an orthographic projection of a midline of the pixel opening extending in at least one direction of the first direction X and the second direction Y on the base substrate, so that the color cast can be reduced, and a display effect can be improved.

In an exemplary implementation, as shown in FIG. 6, the orthographic projection of the pixel opening 801 of the first sub-pixel P1 on the base substrate is located within a range of the orthographic projection of the first power supply line 61 on the base substrate, so that the flatness of the conductive layer nearest to the pixel definition layer in the drive circuit layer at the position of the pixel opening 801 of the first sub-pixel P1 can be improved.

In an exemplary implementation, as shown in FIG. 6, an area of the pixel opening 803 of the third sub-pixel P3 may be greater than an area of the pixel opening 801 of the first sub-pixel P1, and less than an area of the pixel opening 802 of the second sub-pixel P2.

In an exemplary implementation, the first sub-pixel P1 may be a sub-pixel emitting red light, the second sub-pixel P2 may be a sub-pixel emitting blue light, and the third sub-pixel P3 may be a sub-pixel emitting green light.

In an exemplary implementation, as shown in FIG. 6, the display substrate may further include an anode conductive layer located between the drive circuit layer and the pixel definition layer in the direction perpendicular to the plane on which the display substrate is located, wherein the anode conductive layer may include a plurality of anodes 70, an anode 70 may include an anode main body portion 701, and each sub-pixel Pxij may include at least one anode 70;
orthographic projections of pixel openings 80 of the plurality of sub-pixels Pxij on the base substrate are respectively located within ranges of orthographic projections of the plurality of anodes 70 on the base substrate, and there is an overlapping area where an orthographic projection of an anode main body portion 701 of at least one sub-pixel Pxij on the base substrate is overlapped with the orthographic projections of the at least part of signal lines in the at least one conductive layer on the base substrate; among the at least one sub-pixel, an overlapping area corresponding to one sub-pixel Pxij is symmetrical with respect to an orthographic projection of at least one midline of an anode main body portion 701 of the one sub-pixel on the base substrate. As shown in FIG. 6, each anode may include an anode main body portion 701 electrically connected to the drive circuit layer and an anode connection portion 702, an orthographic projection of a pixel opening 80 on the base substrate being within a range of an orthographic projection of a corresponding anode main body portion 701 on the base substrate.

In an exemplary implementation, as shown in FIG. 6, there is a first overlapping area where an orthographic projection of an anode 71 of the first sub-pixel P1 on the base substrate is overlapped with orthographic projections of at least part of signal lines in the second source drain metal layer on the base substrate, there is a second overlapping area where an orthographic projection of an anode 72 of the second sub-pixel P2 on the base substrate is overlapped with orthographic projections of at least part of signal lines in the second source drain metal layer on the base substrate, and there is a third overlapping area where an orthographic projection of an anode 73 of the third sub-pixel P3 on the base substrate is overlapped with orthographic projections of at least part of signal lines in the second source drain metal layer, wherein areas of both the first overlapping area and the second overlapping area are greater than an area of the third overlapping area.

In an exemplary implementation, an orthographic projection of the first overlapping area on the base substrate is symmetrical with respect to an orthographic projection of a midline of an anode main body portion of the first sub-pixel P1 extending in at least one of the first direction X and the second direction Y on the base substrate; an orthographic projection of the second overlapping area on the base substrate is symmetrical with respect to an orthographic projection of a midline of an anode main body portion of the second sub-pixel P2 extending in at least one of the first direction X and the second direction Y on the base substrate; an orthographic projection of the third overlapping area on the base substrate is symmetrical with respect to an orthographic projection of a midline of an anode main body portion of the third sub-pixel P3 extending in at least one of the first direction X and the second direction Y on the base substrate. In an exemplary implementation, an area where an anode main body portion is overlapped with the second source drain metal layer is symmetrical with respect to an orthographic projection of a midline of the anode main body portion extending in at least one direction of the first direction X and the second direction Y on the base substrate, so that the color cast can be reduced, and a display effect can be improved.

In an exemplary implementation, the drive circuit layer may include a plurality of pixel drive circuits, at least part of the sub-pixels may comprise the pixel drive circuits, and at least part of the pixel circuits may include: at least one of first type transistor, at least one of second type transistor; the drive circuit layer may include at least a first semiconductor layer, a first conductive layer, a second conductive layer, a second semiconductor layer, and a third conductive layer sequentially disposed on the base substrate, wherein:
the first semiconductor layer includes at least: an active layer of the first type transistor in the pixel drive circuits; the first conductive layer includes at least: a gate electrode of the first type transistor; the second conductive layer includes at least: a bottom gate of the second type transistor; the second semiconductor layer includes at least: an active layer of the second type transistor; the third conductive layer includes at least: a top gate of the second type transistor.

In an exemplary implementation, as shown in FIG. 6, the first type transistor may include at least a first transistor T1 to a seventh transistor T7, a ninth transistor T9, and the second type transistor may include at least an eighth transistor T8;
in a direction parallel to the plane on which the display substrate is located, in the first direction X, a fourth transistor T4 and a fifth transistor T5 are located on a same side of a third transistor T3, a second transistor T2, a sixth transistor T6 and a seventh transistor T7 are located on the other side of the third transistor T3, and the eighth transistor T8 is located between the second transistor T2 and the fourth transistor T4; in the second direction Y, the fourth transistor T4 and the fifth transistor T5 are respectively located on both sides of the third transistor T3, the fifth transistor T5 to the seventh transistor T7 and the ninth transistor T9 are located on a same side of the third transistor T3, the first transistor T1, the second transistor T2, the fourth transistor T4 and the eighth transistor T8 are located on a same side of the third transistor T3, and the first direction X intersects with the second direction Y.

In an exemplary implementation, as shown in FIG. 6, the pixel drive circuits of the plurality of sub-pixels are arranged in an array, and in a same column of pixel drive circuits, in the first direction X, a first transistor T1 in an i-th row of sub-pixels is located between a seventh transistor T7 and a ninth transistor T9 in an i-1-th row of sub-pixels, where i=2, 3, . . . , M+1, and M is an integer greater than or equal to 1.

In an exemplary implementation, the first conductive layer may further include a first scan signal line extending in the first direction X, a first scan signal line located on the i-th row being electrically connected with the first transistor T1 located on the i-1-th row, a seventh transistor T7 and a ninth transistor T9 located on the i-1-th row.

In an exemplary implementation, the first type transistor may be a low temperature polysilicon transistor, and the second type transistor may be an oxide transistor.

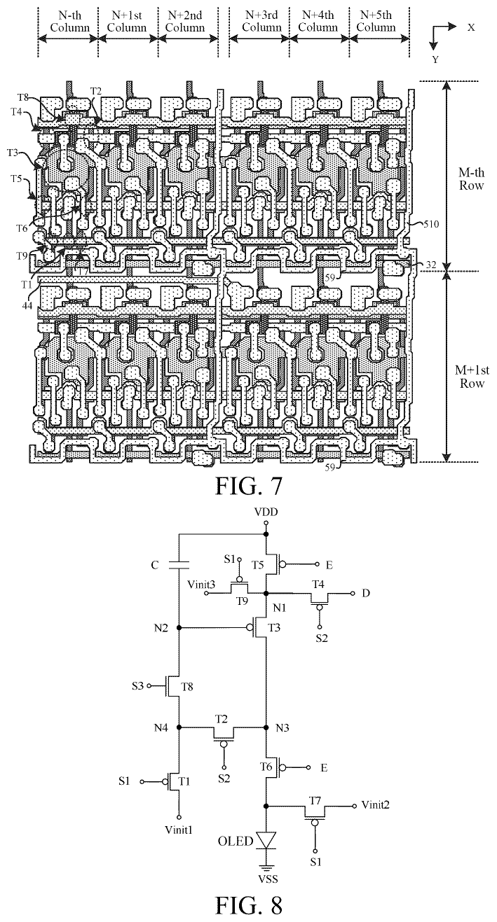

In an exemplary implementation, as shown in FIG. 7, the drive circuit layer may further include a fourth conductive layer which may be on a side of the third conductive layer away from the base substrate in the direction perpendicular to the plane on which the display substrate located, the fourth conductive layer may include a plurality of second initial signal lines 59, a plurality of rows of second initial signal connection lines 510;
the pixel drive circuits of the plurality of sub-pixels Pxij are formed in a plurality of rows, the plurality of second initial signal lines 59 are respectively electrically connected with the plurality of rows of the pixel drive circuits, and in directions parallel to the plane on which the display substrate is located, the plurality of second initial signal lines 59 extend in a first direction X and are arranged at intervals in a second direction Y, wherein the first direction X intersects with the second direction Y;
each row of the second initial signal connection lines includes a plurality of the second initial signal connection lines extending in the second direction Y and arranged at intervals in the first direction X, and in the second direction Y, each row of the second initial signal connection lines is located between two adjacent second initial signal lines 59, and both ends of the plurality of the second initial signal connection lines 510 in each row of the second initial signal connection lines 510 are respectively connected with the two adjacent second initial signal lines 59.

In an exemplary implementation, each second initial signal line 59 is electrically connected with seventh transistors T7 in one row of the pixel drive circuits, and the plurality of second initial signal lines 59 are connected into an integral structure through the plurality of second initial signal connection lines 510, so that the plurality of second initial signal connection lines 510 and the plurality of second initial signal lines 59 form an interconnected grid-like structure, so that the plurality of second initial signal lines 59 have a same potential, and potentials of second initial signals written into first electrodes of the seventh transistors T7 in different rows of pixel drive circuits are substantially the same, thereby improving the display uniformity of the display panel, avoiding poor display of the display substrate, and ensuring the display effect of the display substrate.

In an exemplary implementation, as shown in FIGS. 6 and 7, the drive circuit layer further includes a fifth conductive layer located on a side of the fourth conductive layer away from the base substrate in the direction perpendicular to the plane on which the display substrate is located, the fifth conductive layer may include a plurality of second power supply lines 64, and the second conductive layer may further include a plurality of second power supply connection lines 32, wherein the fifth conductive layer may be referred to as a second source drain metal layer;
in a direction parallel to the plane on which the display substrate is located, the plurality of second power supply lines 64 extend in the second direction Y and are arranged at intervals in the first direction X, the plurality of second power supply connection lines 32 extend in the first direction X and are arranged at intervals in the second direction Y, and the plurality of second power supply lines 64 and the plurality of second power supply connection lines 32 are electrically connected through vias to form a grid-like structure, so that the second power supply wires 62 in the display substrate have substantially a same potential, which is beneficial to improving the uniformity of the panel and ensuring the display effect of the display substrate.

In an exemplary implementation, as shown in FIG. 8, FIG. 8 is an equivalent circuit schematic diagram of a pixel drive circuit provided in an embodiment of the present disclosure and is different from FIG. 4 in that an eighth transistor T8, a ninth transistor T9, a third scan signal line S3, and a third initial signal line Vinit3 are added, wherein the eighth transistor T8 is an N-type transistor (oxide transistor), and the ninth transistor T9 is a P-type transistor (low-temperature polysilicon transistor); the first scan signal line S1 is electrically connected with a control electrode of the first transistor T1, a control electrode of the seventh transistor T7, and a control electrode of the ninth transistor T9; a control electrode of the second transistor T2 and a control electrode of the fourth transistor T4 are electrically connected with the second scan signal line S2; a first electrode of the eighth transistor T8 is connected with a second node N2, a second electrode of the eighth transistor T8 is connected with the fourth node N4, and a control electrode of the eighth transistor T8 is connected with the third scan signal line S3; a second electrode of the first transistor T1 is connected with a fourth node N4; a first electrode of the ninth transistor T9 is connected with the third initial signal line Vinit3, a second electrode of the ninth transistor T2 is connected with a first node N1, and a control electrode of the ninth transistor T9 is connected with the first scan signal line S1.

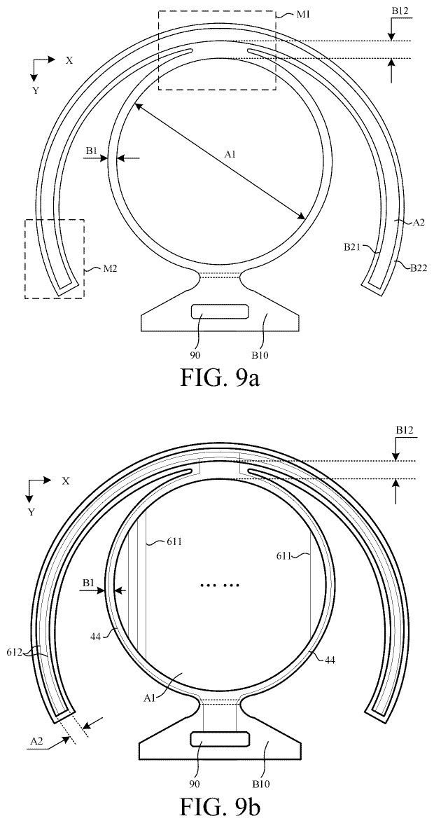

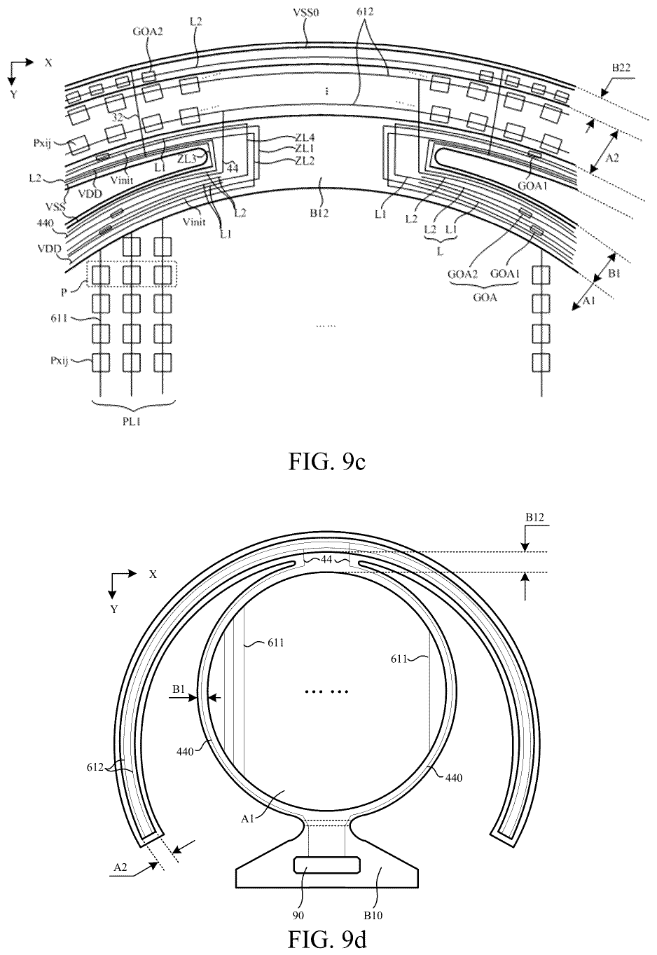

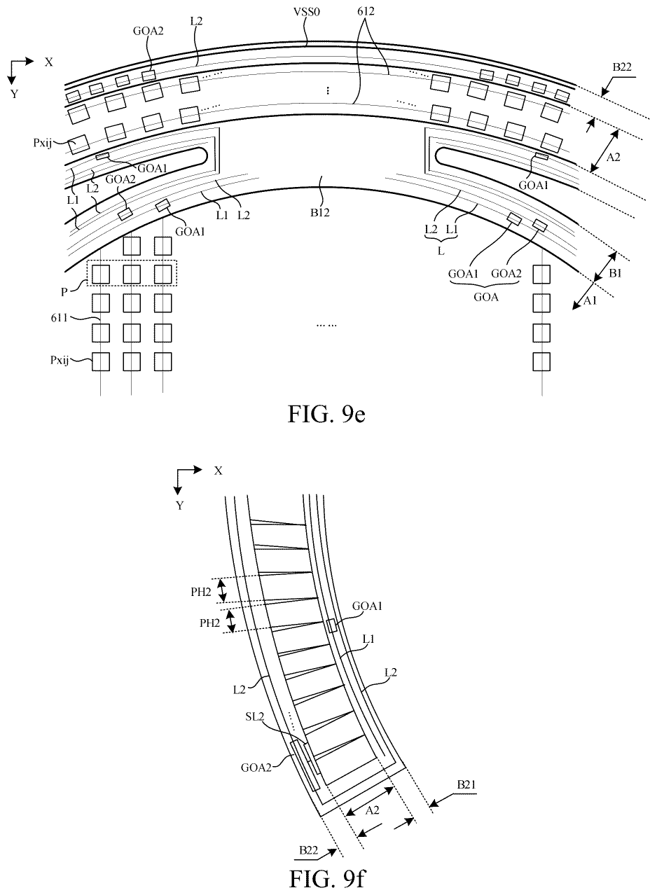

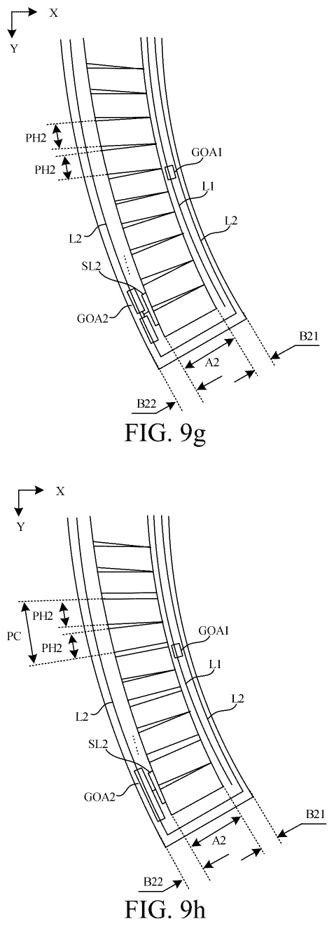

In an exemplary implementation, as shown in FIGS. 9a and 9b, in a direction parallel to the plane on which the display substrate is located, the display substrate includes a first display region A1, a second display region A2 and a connection region B12, the first display region A1 and the second display region A2 are connected through the connection region B12, the second display region A2 at least partially surrounds the first display region A1, and the pixel drive circuits of the plurality of sub-pixels are located in the first display region A1 and the second display region A2 and are formed in a plurality of columns;
as shown in FIGS. 6, 7 and 9a, the third conductive layer may further include a plurality of second data signal connection lines 44, and the fifth conductive layer may further include a plurality of first data signal lines 611 and a plurality of second data signal lines 612 (that is, data signal lines may include the first data signal lines 611 and the second data signal lines 612); the plurality of first data signal lines 611 are respectively electrically connected with a plurality of columns of pixel drive circuits located in the first display region A1, and the plurality of second data signal lines 612 are electrically connected with a plurality of columns of pixel drive circuits located in the second display region A2; the plurality of second data signal connection lines 44 are located in the second display region A2, and are respectively electrically connected with the plurality of columns of pixel drive circuits located in the second display region A2. In an exemplary implementation, the structures shown in FIGS. 6 and 7 are schematic diagrams of a structure of the two rows and six columns of the pixel drive circuits in the second display region A2. The pixel drive circuits in the first display region A1 are different from FIGS. 6 and 7 in that the second data signal connection lines 44 are not provided, that is, the structure of the pixel drive circuits in the first display region A1 is that of FIGS. 6 and 7 when the second data signal connection lines 44 are removed.

As shown in FIGS. 9a and 9b, a first outer bezel B1 is provided on a periphery of the first display region A1, and a second inner bezel B21 and a second outer bezel B22 may be respectively provided on both sides of the second display region A2. In FIG. 9b, two second data signal lines are exemplarily shown in the second display region A2, but actually more than two, and the number of second data signal lines 612 disposed in the second display region A2 may be, but is not limited to, one of 24, 48, and 72. As shown in FIG. 9b, one end of each second data signal connection line 44 may be electrically connected to one of the second data signal lines 612 in the second display region A2, and the other end may extend along the outer bezel B1 of the first display region A1 to the bonding region B10, and is electrically connected with the driver chip 90 located in the bonding region B10. In an exemplary implementation, the number of second data signal lines 612 matches the number of second data signal connection lines 44, and each of the second data signal lines 612 is electrically connected with the driver chip 90 via one second data signal connection line 44.

In an exemplary implementation, the plurality of sub-pixels Pxij form a plurality of pixel units P, the plurality of pixel units P are arranged in an array, a pixel unit comprises at least three adjacent sub-pixels Pxij, a second power supply line 64 and a second initial signal connection line 510 are disposed between two adjacent columns of pixel units, and a second power supply connection line 32 and a second data signal connection line 44 are located between two adjacent rows of pixel units.

A display substrate is also provided in an embodiment of the present disclosure, as shown in FIGS. 9a and 9b, the display substrate may include a first display region A1, a second display region A2, a bonding region B10 and a connection region B12, wherein the first display region A1 is connected with the second display region A2 through the connection region A12, the second display region A2 at least partially surrounds the first display region A1, and the bonding region B10 is located on a side of the first display region A1 in a direction parallel to a plane on which the display substrate is located;
the second display region A2 is provided with a plurality of second data signal lines 612 and a plurality of second data signal connection lines 44; one ends of the plurality of second data signal connection lines 44 are respectively electrically connected with the plurality of second data signal lines 612, and the other ends are electrically connected with elements disposed in the bonding region B10.

In an exemplary implementation, the bonding region B10 and the connection B12 may be located on two opposite sides of the first display region A1 in a direction parallel to the plane on which the display substrate is located, and the elements disposed in the bonding region B10 may include a driver chip 90, one ends of the plurality of second data signal connection lines 44 being electrically connected with the driver chip 90.

In an exemplary implementation, as shown in FIG. 9c, FIG. 9c is a schematic enlarged view of M1 position in FIG. 9a, wherein the second display region A2 is provided with a plurality of pixel units P, the plurality of pixel units P forming a plurality of second pixel unit rows and a plurality of second pixel unit columns, the plurality of second pixel unit columns being arranged sequentially in a direction from the first display region A1 to the second display region A2, and distances between two adjacent second pixel unit rows are sequentially increased from a first second pixel unit column to a last second pixel unit column.

In an exemplary implementation, the first display region A1 may be provided with a plurality of pixel units forming a plurality of first pixel unit rows and a plurality of first pixel unit columns PL1, the plurality of first pixel unit columns PL1 being arranged in the first direction X, and the plurality of pixel units in each of the first pixel unit columns being arranged in the second direction Y. In an exemplary implementation, an arrangement direction of the plurality of pixel units in the first pixel unit column and an arrangement direction of a plurality of pixel units P in a second pixel unit column are at a certain angle.

In an exemplary implementation, a first pixel unit column may include three adjacent columns of sub-pixels, and a second pixel unit column may include three adjacent columns of sub-pixels.

In an exemplary implementation, as shown in FIGS. 9b and 9c, the first display region A1 is provided with a plurality of first data signal lines 611, an extension direction of the plurality of first data signal lines 611 and an arrangement direction of a plurality of pixel units P in a first pixel unit column PL1 are consistent, each of the first data signal lines 611 being electrically connected with a plurality of sub-pixels Pxij in a sub-pixel column in the first pixel unit column PL1; an extension direction of the plurality of second data signal lines 612 in the second display region A2 and an arrangement direction of a plurality of pixel units in a second pixel unit column are consistent, each of the second data signal lines 612 being electrically connected with a plurality of sub-pixels Pxij in a sub-pixel column in a second pixel unit column.

In an exemplary implementation, the first display region A1 has a shape of a circular, and the second display region A2 has a shape of a ribbon that at least partially surrounds the first display region A1. As shown in FIGS. 9a and 9b, the shape of the ribbon of the second display region A2 may be an arc-shaped shape.

In an exemplary implementation, as shown in FIG. 9d, the display substrate may further include a first outer bezel region B1, wherein the first outer bezel region B1 is disposed on the periphery of the first display region A1, the first outer bezel region B1 including the connection region A12 and the bonding region B10, the first outer bezel region B1 being provided with a plurality of second data signal adapter lines 440, the second data signal adapter lines 440 and the second data signal connection lines 44 being located in different conductive layers;
the second data signal connection lines 44 extend from the second display region A2 to the connection region B12, the plurality of second data signal adapter lines 440 extend from the connection region B12 along the first outer bezel region B1 to the bonding region B10, one ends being electrically connected with the plurality of second data signal connection lines 44 located in the connection region B12, and the other ends being electrically connected with the driver chip 90.

In an exemplary implementation, the second data signal adapter lines 440 may be located in the fourth conductive layer (i.e., the first source drain metal layer), the second data signal connection lines 44 may be located in the third conductive layer (i.e., the third gate metal layer), and in the connection region B12, the second data signal adapter lines 440 and corresponding second data signal connection lines 44 may be connected through vias.

In an exemplary implementation, as shown in FIGS. 9a and 9b, the display substrate may further include a second outer bezel region B22 and a second inner bezel region B21, the second outer bezel region B22 and the second inner bezel region B21 being located on both sides of the second display region A2 in a direction from the first display region A1 to the second display region A2.

In an exemplary implementation, as shown in FIG. 9c, the second inner bezel region B21 is connected with the first outer bezel region B1 through the connection region B12, and the first outer bezel region B1 and the second inner bezel region B21 are provided with a second power supply signal supply line VSS, wherein the second power supply signal supply line is electrically connected with the driver chip 90 and extends to the second inner bezel region B21 via the first outer bezel region B1.

In an exemplary implementation, the display substrate may further include a cathode layer, the second display region A2 includes the second power supply connection lines 32 electrically connected with the second power supply signal supply line VSS in the second inner bezel region B21 (as shown in FIGS. 6 and 7), and the second outer bezel region B22 includes a second power supply lap line VSS0 overlapped with the cathode layer and the second power supply connection lines 32, wherein the second power supply lap line VSS0 is electrically connected with the second power supply connection lines 32 and the cathode layer through vias. The second power supply lap line VSS0 acquires a second power supply signal from the driver chip through the second power supply connection lines 32 and the second power supply signal supply line VSS, and supplies it to the cathode layer.

In an exemplary implementation, the second power supply signal supply line VSS located in the first outer bezel region B1 is overlapped with the cathode layer and is electrically connected with the cathode layer through a via.

In an exemplary implementation, a line width of the second power supply signal supply line VSS in the second inner bezel region B21 is small and is not electrically connected with the cathode layer, so that the bezels of the second display region A2 and the first display region A1 can be reduced.

In an exemplary implementation, in a direction from the second display region A2 to the second inner bezel region B21, the second inner bezel region B21 sequentially includes: a first type gate drive circuit GOA1 and a first type drive signal line L1, an initial signal line Vinit, a first power supply signal supply line VDD, and a second power supply signal supply line VSS electrically connected with the first type gate drive circuit;
in a direction from the second display region A2 to the second outer bezel region B22, the second outer bezel region B22 sequentially includes: a second type gate drive circuit GOA2 and a second type drive signal line L2 and a second power supply lap line VSS0 electrically connected with the second type gate drive circuit, wherein the second type drive signal line L2 is electrically connected with the driver chip 90 via the second outer bezel region V22, the second inner bezel region B21, and the first outer bezel region B1.

In an exemplary implementation, the first type gate drive circuit GOA1 may include a gate drive circuit providing a scan signal to the second transistors T2 and the fourth transistors T4 (that is, providing a scan signal to the second scan signal line S2), and the second type gate drive circuit GOA2 may include a gate drive circuit providing a first scan signal to the first scan signal line S1 (that is, providing a first scan signal to the first transistors T1, the seventh transistors T7, and the ninth transistors T9), a gate drive circuit providing a third scan signal to the third scan signal line S3 (that is, providing a third scan signal line to the eighth transistor T8), and a gate drive circuit providing a light emitting control signal to the light emitting control line E (that is, providing a light emitting control signal to the fifth transistors T5 and the sixth transistors T6).

In an exemplary implementation, the connection region B12 is provided with an initial signal adapter electrode ZL1 disposed in a different layer from the initial signal line Vinit, a first power supply adapter electrode ZL2 disposed in a different layer from the first power supply signal supply line VDD, a second power supply adapter electrode ZL3 disposed in a different layer from or in a same layer as the second power supply signal supply line VSS, and a drive signal adapter electrode ZL4 disposed in a different layer from the first type drive signal line L1;
in a direction from the first display region A1 to the first outer bezel region B1, the first outer bezel region B1 sequentially includes: a first power supply signal supply line VDD, an initial signal line Vinit, a first type drive signal line L1, and a second power supply signal supply line VSS;
the first power supply signal supply line VDD located in the first outer bezel region B1 is electrically connected with the first power supply signal supply line VDD located in the second inner bezel region B21 through the first power supply adapter electrode ZL2; the initial signal line Vinit located in the first outer bezel region B1 is electrically connected with the initial signal line Vinit located in the second inner bezel region B21 through the initial signal adapter electrode ZL1; the first type drive signal line L1 located in the first outer bezel region B1 is electrically connected with the first type drive signal line L1 through the drive signal adapter electrode ZL4; and the second power supply signal supply line VSS located in the first outer bezel region B1 is electrically connected with the second power supply signal supply line VSS located in the second inner bezel region B21 through the second power supply adapter electrode ZL3.

In an exemplary implementation, as shown in FIG. 9c, in the direction from the first display region A1 to the first outer bezel region B1, a first type gate drive circuit GOAL and a first type drive signal line L1 electrically connected with the first type gate drive circuit GOA1, a second type gate drive circuit GOA2 and a second type drive signal line L2 electrically connected with the second type gate drive circuit GOA2 may also be provided in the first outer bezel region B1 between the initial signal line Vinit and the second power supply signal supply line VSS.

In an exemplary implementation, as shown in FIGS. 9c and 9e, both first type drive signal lines and second type drive signal lines located in the first outer bezel region B1 include two sets, wherein one set of the first type drive signal lines L1 is electrically connected with the first type gate drive circuit GOA1 providing the scan signal to the first display region A1, and the other set of the first type gate drive signal lines L1 is electrically connected with the first type gate drive circuit GOA1 located in the second inner bezel region B21 providing the scan signal to the second display region A2; one set of the second type drive signal lines L2 is electrically connected with the second type gate drive circuit GOA2 providing the scan signal to the first display region A1, and the other set of the second type gate drive signal lines L2 is electrically connected with the second type gate drive circuit GOA2 located in the second outer bezel region B22 providing the scan signal to the second display region A2. The first type gate drive circuit GOA1 located in the first inner bezel region B1 and the first type gate drive circuit GOA1 located in the second inner bezel region B21 are connected with different first type drive signal lines L1, and the second type gate drive circuit GOA2 located in the first inner bezel region B1 and the second type gate drive circuit GOA2 located in the second outer bezel region B22 are connected with different second type drive signal lines L2, Thus, on the one hand, it can enable the first display region A1 and the second display region A2 to be driven separately and flexibly, and on the other hand, it can enable loads on the second type gate drive circuit GOA2 and the first type drive signal line L1 connected with the second type gate drive circuit GOA2 located in the second outer bezel region B22 and the first type gate drive circuit GOA1 located in the second inner bezel region B21 to be reduced, and it can enable brightnesses of the first display region A1 and the second type drive signal line L1 to be controlled to be as consistent as possible, so that it is avoided that a load on a second type drive signal line L2 is too large when the second type drive signal line L2 is connected with the second type gate drive circuit GOA2 located in the first outer bezel region B1 which causes potentials of the second type drive signal lines L2 received by the second type drive circuit GOA2 located in the first outer bezel B22 and the second type drive circuit GOA2 located in the first outer bezel B1 to be inconsistent, and it is avoided that a load on a first type drive signal line L1 is too large when the first type drive signal line L1 is connected with the first type gate drive circuit GOA1 located in the first outer bezel region B1 which causes potentials of the first type drive signal lines L1 received by the first type drive circuit GOA1 located in the first inner bezel B21 and the first type drive circuit GOA1 located in the first outer bezel B1 to be inconsistent.

In an exemplary implementation, the initial signal line Vinit may include the above-described first initial signal line Vinit1 connected with the first electrodes of the first transistors T1, the second initial signal line Vinit2 connected with the first electrodes of the seventh transistors T7, and the third initial signal line Vinit3 connected with the first electrodes of the ninth transistors T9.

In an exemplary implementation, as shown in FIG. 9f, the second display region A2 may further include a plurality of second type scan signal lines SL2, an output terminal of each second type gate drive circuit GOA2 is electrically connected with two corresponding second type scan signal lines SL2, and each second type scan signal line SL2 is electrically connected with a plurality of sub-pixels in one of second pixel unit rows PH2.

In an exemplary implementation, as shown in FIG. 9f, sizes of each second type gate drive circuit GOA2 and its two adjacent second pixel unit rows PH2 in an extension direction of the second outer bezel region B22 are consistent;
or, as shown in FIG. 9g, each second type gate drive circuit GOA is divided into two parts of circuits connected with each other, and in the extension direction of the second outer bezel region, sizes of the two parts of circuits are consistent respectively with the two adjacent second pixel unit rows;
or, as shown in FIG. 9h, the two adjacent second pixel unit rows are served as one unit module PC, and in the extension direction of the second outer bezel region B22, a distance between adjacent two unit modules PC is greater than a distance between two second pixel units P in a same unit module, and sizes of each second type gate drive circuit and its one adjacent unit module PC are consistent in the extension direction of the second outer bezel region B22.

In an embodiment of the present disclosure, the first display region can be served as a main screen display region, and the second display region can be served as a secondary screen display region. In an exemplary implementation, the main screen display region may be served as the secondary screen display region, and the secondary screen display region may be served as the main screen display region.

In an exemplary implementation, an edge ring display (ERD) watch may include the main screen display region and the secondary screen display region, wherein the first display region A1 may be served as the main screen display region of the edge ring watch and the second display region A2 may be served as the secondary screen display region of the edge ring watch. In an exemplary implementation, as shown in FIG. 9i, FIG. 9i is a schematic diagram of a structure of the ERD watch obtained after the display substrate is assembled, wherein the first display region A1 may be located on a front surface of the watch, and the second display region A2 may be located on a side surface of the watch in FIG. 9a.

In an exemplary implementation, the first direction X may be a row direction of the plurality of pixel units, and the second direction Y may be a column direction of the plurality of pixel units.

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate (or substrate) using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, taking 12 sub-pixels (2 sub-pixel rows and 6 sub-pixel columns) in a display area (AA) as an example, a manufacturing process of a display substrate may include following operations.

(101) A base substrate is prepared on a glass carrier plate. In an exemplary implementation, the base substrate may be a flexible substrate, or a rigid substrate. The rigid substrate may include, but is not limited to, one or more of glass and quartz. The flexible substrate may be, but is not limited to, one or more of polyethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, an adhesive layer, a second flexible material layer, and a second inorganic material layer which are stacked. Materials of the first flexible material layer and the second flexible material layer may be Polyimide (PI), Polyethylene Terephthalate (PET), or a polymer soft thin film subjected to surface treatment, etc. Materials of the first inorganic material layer and the second inorganic material layer may be Silicon Nitride (SiNx), Silicon Oxide (SiOx), or the like, so as to improve a water-oxygen resistance capability of the base substrate. The first inorganic material layer and the second inorganic material layer are also referred to as barrier layers. In an exemplary implementation, taking a stacked structure of PI1/Barrier1/a-si/PI2/Barrier2 as an example, its preparation process may include: first coating a layer of polyimide on a glass carrier board, after the layer of polyimide is cured to form a film, a first flexible material (PI1) layer is formed; then depositing a layer of barrier thin film on the first flexible layer to form a first barrier (Barrier 1) layer overlaying the first flexible material layer; then depositing a layer of amorphous silicon thin film on the first barrier layer to form an amorphous silicon (a-si) layer overlaying the first barrier layer; then coating another layer of polyimide on the amorphous silicon layer, after this layer of polyimide is cured to form a film, a second flexible material (PI2) layer is formed; and then depositing a layer of barrier thin film on the second flexible layer to form a second barrier (Barrier 2) layer overlaying the second flexible layer, so as to complete preparation of the base substrate.

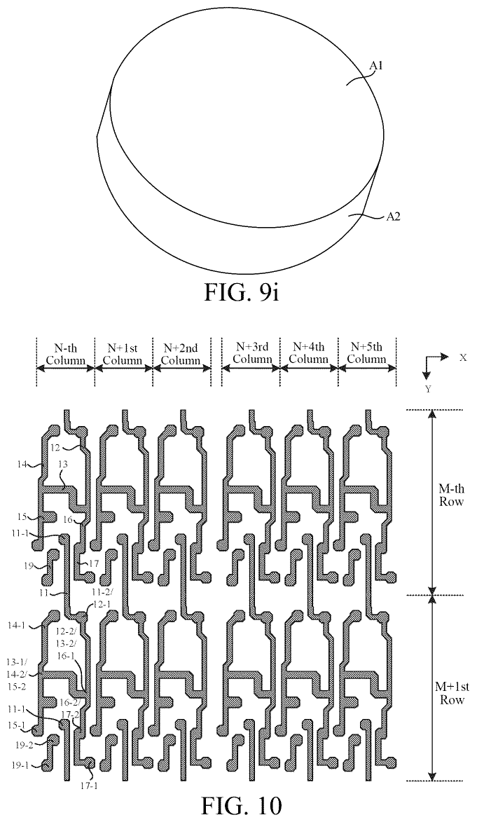

(102) A pattern of a first semiconductor layer is formed. In an exemplary implementation, forming a pattern of a first semiconductor may include: sequentially depositing a first insulation thin film and a first semiconductor thin film on the base substrate, patterning the first semiconductor thin film through a patterning process to form a first insulation layer covering a pattern of the shield layer, and a pattern of a first semiconductor disposed on the first insulation layer, as shown in FIG. 10, and FIG. 10 is a schematic plan view of the first semiconductor layer with twelve sub-pixels.

In an exemplary implementation, the pattern of the first semiconductor layer of each sub-pixel may include the active layer 11 of the first transistor T1 to the active layer 17 of the seventh transistor T7, the active layer 19 of the eighth transistor T9, and the active layer 11 of the first transistor T1 to the active layer 17 of the seventh transistor T7 are connected to each other to form an integral structure.

In an exemplary implementation, in the first direction X, the active layer 14 of the fourth transistor T4 and the active layer 15 of the fifth transistor T5 are located on a same side of the active layer 13 of the third transistor T3, and the active layer 12 of the second transistor T2, the active layer 16 of the sixth transistor T6 and the active layer 17 of the seventh transistor T7 are located on the other side of the active layer 13 of the third transistor T3; in the second direction Y, the active layer 14 of the fourth transistor T4 and the active layer 15 of the fifth transistor T5 are located on both sides of the active layer 13 of the third transistor T3, and the active layer 15 of the fifth transistor T5, the active layer 16 of the sixth transistor T6, the active layer 17 of the seventh transistor T7, and the active layer 19 of the ninth transistor T9 are located on a same side of the active layer 13 of the third transistor T3, the active layer 14 of the fourth transistor T4, the active layer 12 of the second transistor T2, and the active layer 11 of the first transistor T1 are located on a same side of the active layer 13 of the third transistor T3, the active layer 17 of the seventh transistor T7 is located on a side of the active layer 16 of the sixth transistor T6 away from the active layer 12 of the second transistor T2, the active layer 11 of the first transistor T1 is located on a side of the active layer 12 of the second transistor T2 away from the active layer 16 of the second transistor T6, a first region 11-1 of the active layer 11 of the second transistor T1 extends to the active layers of adjacent rows, and is located between the active layer 19 of the ninth transistor T9 and the active layer 17 of the seventh transistor T7 in the first direction X.

In an exemplary implementation, taking a sub-pixel of the M-th row and the N-th column as an example, in the first direction X, the active layer 14 of the fourth transistor T4 and the active layer 15 of the fifth transistor T5 are located on a side of the active layer 13 of the third transistor T3 away from the sub-pixels of the N+1st column, and the active layer 12 of the second transistor T2, the active layer 16 of the sixth transistor T6, and the active layer of the seventh transistor T7 are located on a side of the active layer 13 of the third transistor T3 away from the sub-pixels of the N−1st column; in the second direction Y, the active layer 11 of the first transistor T1, the active layer 12 of the second transistor T2, and the active layer 14 of the fourth transistor T4 are located on a side of the active layer 13 of the third transistor T3 away from the sub-pixels of the M+1st row, the active layer 15 of the fifth transistor T5, the active layer 16 of the sixth transistor T6, the active layer 17 of the seventh transistor T7, and the active layer 19 of the ninth transistor T9 are located on a side of the active layer 13 of the third transistor T3 away from the sub-pixels of the M-1st row, the active layer 17 of the seventh transistor T7 is located on a side of the active layer 16 of the sixth transistor T6 away from the active layer 13 of the third transistor T3, and the active layer 11 of the first transistor T1 is located on a side of the active layer 12 of the second transistor T2 away from the active layer 13 of the third transistor T3.

In an exemplary implementation, the active layer 13 of the third transistor T3 may be shaped in a “Z” shape, the active layer 11 of the first transistor T1, the active layer 12 of the second transistor T2, the active layer 14 of the fourth transistor T4, and the active layer 19 of the ninth transistor T9 may be shaped in an “I” shape, the active layer 15 of the fifth transistor T5 may be shaped in a “Z” shape, the active layer 16 of the sixth transistor T6 may be shaped in a polyline shape extending in the second direction Y, and the active layer 17 of the seventh transistor T7 may be shaped in an “L” shape.

In an exemplary implementation, an active layer of each transistor may include a first region, a second region, and a channel region located between the first region and the second region. In an exemplary implementation, a first region 13-1 of the active layer 13 of the third transistor T3 may serve as a second region 14-2 of the active layer 14 of the fourth transistor T4 and a second region 15-2 of the active layer 15 of the fifth transistor T5, a second region 13-2 of the active layer 13 of the third transistor T3 may serve as a second region 12-2 of the active layer 12 of the second transistor T2, a first region 16-1 of the active layer 16 of the sixth transistor T6, a second region 16-2 of the active layer 16 of the sixth transistor T6 may serve as a second region 17-2 of the active layer 17 of the seventh transistor T7, a second region 11-2 of the active layer 11 of the first transistor T1 may serve as a first region 12-1 of the active layer 12 of the second transistor T2, and a first region 11-1 of the active layer 11 of the first transistor T1, a first region 14-1 of the active layer 14 of the fourth transistor T4, a first region 15-1 of the active layer 15 of the fifth transistor T5, and a first region 17-1 of the active layer 17 of the seventh transistor T7, and a first region 19-1 and a second region 19-2 of the active layer 19 of the ninth transistor T9 may be disposed separately.

In an exemplary implementation, a first region 11-1 of an active layer 11 of a first transistor T1 in a sub-pixel of an i-th rows may be disposed in a sub-pixel of an i-1st row, where i=2, 3, . . . , M+1.

In an exemplary implementation, shapes of the active layers in multiple sub-pixels may be the same.

In an exemplary implementation, the first semiconductor layer may be made of poly-crystalline silicon (p-Si), i.e., the first transistor T1 to the third transistor T7, and the ninth transistor T9 are LTPS thin film transistors. In an exemplary implementation, patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a polysilicon thin film. Subsequently, the poly silicon thin film is patterned to form the pattern of the first semiconductor layer.

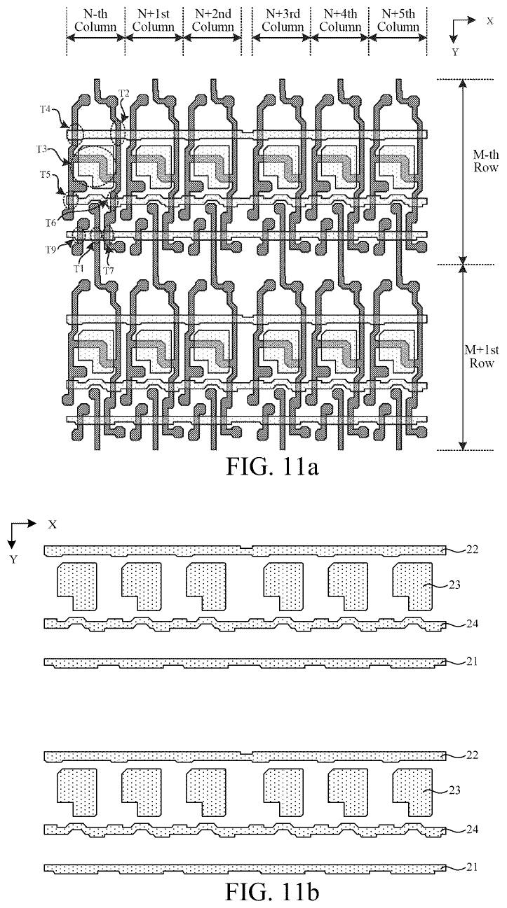

(103) Forming a pattern of a first conductive layer. In an exemplary implementation, forming the pattern of the first conductive layer may include: sequentially depositing a second insulation thin film and a first conductive thin film on the base substrate where the above-mentioned patterns are formed, and patterning the first conductive thin film through a patterning process to form a second insulation layer that covers the pattern of the first semiconductor layer and the pattern of the first conductive layer disposed on the second insulation layer, as shown in FIG. 11a and FIG. 11b, FIG. 11b is a planar schematic view of the first conductive layer in FIG. 11a. In an exemplary implementation, the first conductive layer may be referred to as a first gate metal (GATE1) layer.

In an exemplary implementation, the pattern of the first conductive layer may at least include: a first scan signal line 21, a second scan signal line 22, a first plate 23 of a storage capacitor, a light emitting control line 24, wherein main body portions of the first scan signal line 21, the second scan signal line 22, the light emitting control line 24 may extend in the first direction X, and in a same sub-pixel, the first scan signal line 21, the second scan signal line 22, the first plate 23 of the storage capacitor, the light emitting control line 24 are arranged at intervals in the second direction Y.

In an exemplary implementation, in the second direction Y, the second scan signal line 22 and the light emitting control line 24 are located on two sides of the first plate 23 of the storage capacitor, the first scan signal line 21 is located on one side of the second scan signal line 22 away from the first plate 23 of the storage capacitor, and the third scan signal line 35 is located on one side of the light emitting control line 24 away from the first plate 23 of the storage capacitor. For example, the second scan signal line 22, the first plate 23 of the storage capacitor, the light emitting control line 24, and the first scan signal line 21 are arranged sequentially in the second direction.

Taking the sub-pixel in the M-th row and the N-th column as an example, in the second direction Y, the second scan signal line 22 may be located on a side of the first plate 23 of the storage capacitor in the current sub-pixel close to the sub-pixels in the M-1st row; the light emitting control line 24 may be located on a side of the first plate 23 of the storage capacitor in the current sub-pixel close to the sub-pixels in the M+1st row; and the first scan signal line 21 may be located on a side of the light emitting control line 24 away from the first plate 23 of the storage capacitor.

In an exemplary implementation, the first plate 23 may be located between the light emitting control line 24 and the second scan signal line 22, the first plate 23 may be in a shape of a rectangle, corners of the rectangle may be chamfered, edges of the rectangle may be in a polyline shape, and there is an overlapping area between an orthographic projection of the first plate 23 on the base substrate and an orthographic projection of the active layer of the third transistor T3 on the base substrate. In an exemplary embodiment, the first plate 23 may simultaneously serve as a plate of the storage capacitor and the control electrode of the third transistor T3.

In an exemplary implementation, a region where the light emitting control line 24 (i.e., the light emitting control line E in FIG. 8) is overlapped with the active layer of the fifth transistor T5 may serve as the control electrode of the fifth transistor T5, a region where the light emitting control line 24 is overlapped with the active layer of the sixth transistor T6 may serve as the control electrode of the sixth transistor T6, a region where the first scan signal line 21 (i.e., the first scan signal line S1 in FIG. 8) is overlapped with the active layer of the first transistor T1 may serve as the control electrode of the first transistor T1, a region where the first scan signal line 21 is overlapped with the active layer of the seventh transistor T7 may serve as the control electrode of the seventh transistor T7, a region where the first scan signal line 21 is overlapped with the active layer of the ninth transistor T9 may serve as the control electrode of the ninth transistor T9, a region where the second scan signal line 22 (i.e., the second scan signal line S2 in FIG. 8) is overlapped with the active layer of the second transistor T2 may serve as the control electrode of the second transistor T2, and a region where the second scan signal line 22 is overlapped with the active layer of the fourth transistor T4 may serve as the control electrode of the fourth transistor T4.

In an exemplary implementation, the first scan signal line 21, the second scan signal line 22 and the light emitting control line 24 may be designed with an equal width or with non-equal widths, thereby not only a layout of a pixel structure may be facilitated, but also a parasitic capacitance between signal lines may be reduced.

In an exemplary implementation, after the pattern of the first conductive layer is formed, a conductive processing may be performed on the semiconductor layer by using the first conductive layer as a shield, a semiconductor layer in a region shielded by the first conductive layer forms channel regions of the first transistor T1 to the seventh transistor T7, and the ninth transistor T9, and a semiconductor layer in a region not shielded by the first conductive layer is made to be conductive. That is, all of the first regions and the second regions of the active layer 11 of the first transistor T1 to the active layer 17 of the seventh transistor T7, and the active layer 19 of the ninth transistor T9 are made to be conductive.

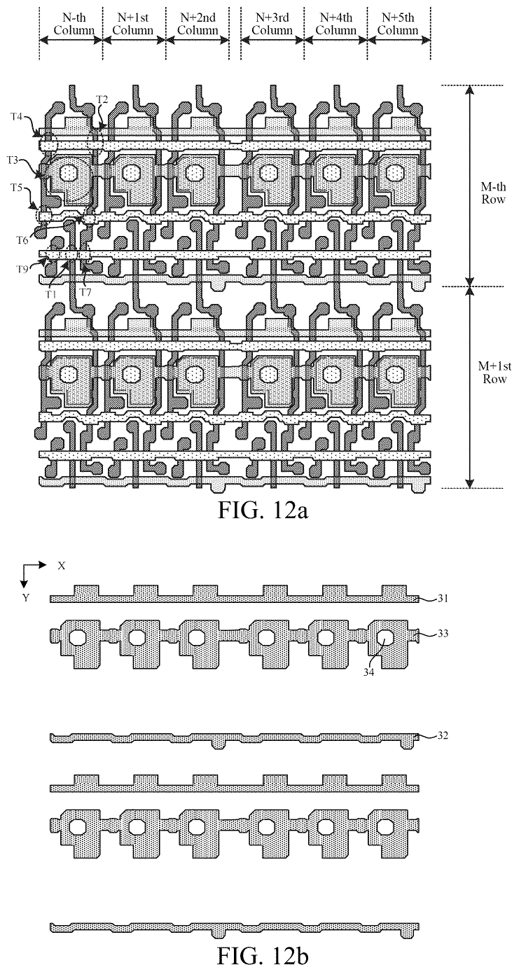

(104) A pattern of a second conductive layer is formed. In an exemplary implementation, forming the pattern of the second conductive layer may include: depositing sequentially a third insulation thin film and a second conductive thin film on the base substrate where the aforementioned patterns are formed, and patterning the second conductive thin film through a patterning process to form a third insulation layer covering the first conductive layer and the pattern of the second conductive layer disposed on the third insulation layer, as shown in FIG. 12a and FIG. 12b, FIG. 12a is a diagram of a planar structure of twelve sub-pixels, and FIG. 12b is a planar schematic view of the second conductive layer in FIG. 12a. In an exemplary implementation, the second conductive layer may be referred to as a second gate metal (GATE2) layer.

In an exemplary implementation, the pattern of the second conductive layer at least includes: a first shield line 31, a second power supply connection line 32, and a second plate 33 of the storage capacitor. And the main body portions of the first shield line 31 and the second power supply connection line 32 may extend in the first direction X. The second plate 33 of the storage capacitor may serves as the other plate of the storage capacitor. In the second direction Y, the first shield line 31 and the second power supply connection line 32 may be located on both sides of the second plate 33, respectively. For example, in a same sub-pixel, the first shield line 31, the second plate 33 of the storage capacitor (i.e., the storage capacitor C in FIG. 8), and the second power supply connection line 32 may be arranged in the second direction Y.

In an exemplary implementation, the first shield line 31 is configured as a shield layer of the eighth transistor T8, to shield a channel of the eighth transistor T8, and ensure electrical performance of the oxide eighth transistor T8. In an exemplary implementation, signals of the first shield line 31 and a third scan signal line subsequently formed may be the same, i.e., the first shield line 31 and the third scan signal line 41 subsequently formed are connected in parallel, and are connected to a same signal source, so that the first shield line 31 may serve as a bottom gate electrode (i.e., a bottom control electrode) of the eighth transistor T8, forming a eighth transistor T8 with a double-gate structure.

In an exemplary implementation, a profile of the second plate 33 may be in a shape of a rectangle whose corners may be chamfered and edges may be in a polyline shape, there is an overlapping area between an orthographic projection of the second plate 33 on the base substrate and an orthographic projection of the first plate 23 on the base substrate, and the first plate 23 and the second plate 33 form the storage capacitor of the pixel drive circuit. The second plate 33 is provided with an opening 34, and the opening 34 may be located in the middle of the second plate 33. The opening 34 may be rectangular and enables the second plate 33 to form an annular structure. The opening 34 exposes the third insulation layer covering the first plate 23, and an orthographic projection of the first plate 23 on the base substrate contains an orthographic projection of the opening 34 on the base substrate. In an exemplary embodiment, an opening 34 is configured to accommodate a twelfth via subsequently formed, which is located in the opening 34 and exposes a first plate 34, so that a first electrode of an eighth transistor T8 subsequently formed is connected with the first plate 23.

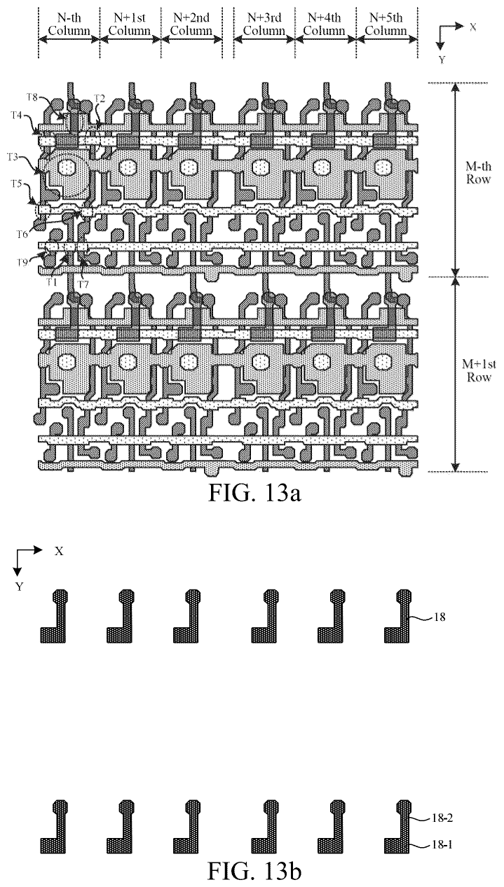

(105) A pattern of a second semiconductor layer is formed. In an exemplary implementation, forming a pattern of a second semiconductor layer may include: depositing a fourth insulation thin film and a second semiconductor thin film sequentially on the base substrate on which the above-mentioned patterns are formed, patterning the second semiconductor thin film through a patterning process to form a fourth insulation layer covering the base substrate and the pattern of the second semiconductor layer disposed on the fourth insulation layer, as shown in FIG. 13a to FIG. 13b, FIG. 13a is a diagram of a planar structure of twelve sub-pixels, and FIG. 13b is a planar schematic diagram of the second conductive layer in FIG. 13a.

In an exemplary implementation, the pattern of the second semiconductor layer in each sub-pixel at least includes the active layer 18 of the eighth transistor T8.

In an exemplary implementation, the active layer 28 of the eighth transistor T8 may be in a shape of letter “L”, and the first region 18-1 and the second region 18-2 of the active layer 18 of the eighth transistor T8 may be separately disposed.

In an exemplary implementation, shapes of the second semiconductor layers in a plurality of sub-pixels row may be the same.

In an exemplary implementation, in the plane on which the display substrate is located, in the first direction X, the active layer 18 of the eighth transistor T8 may be located between the active layer 14 of the fourth transistor T4 and the active layer 12 of the second transistor T2; in the second direction Y, the active layer 18 of the eighth transistor T8 may be located on a side of the active layer 23 of the third transistor T3 away from the active layer 15 of the fifth transistor T5 and the active layer 16 of the sixth transistor T6.

In an exemplary implementation, taking the sub-pixel in the M-th row and the N-th column as an example, in the first direction X, the active layer 11 of the first transistor T1, the active layer 12 of the second transistor T2, and the active layer 16 of the sixth transistor T6 are located on a side of the active layer 23 of the third transistor T3 away from the sub-pixels in the N-1st column, the active layer 14 of the fourth transistor T4, the active layer 15 of the fifth transistor T5 are located on a side of the active layer 23 of the third transistor T3 away from the sub-pixels in the N+1st column, and the active layer 18 of the eighth transistor T8 is located between the active layer 14 of the fourth transistor T4 and the active layer 12 of the second transistor T2; in the second direction Y, the active layer 12 of the second transistor T2, the active layer 14 of the fourth transistor T4, and the active layer 18 of the eighth transistor T8 are located on a side of the active layer 13 of the third transistor T3 away from the sub-pixels in the M+1st row.

In an exemplary implementation, the second semiconductor layer may be made of an oxide, i.e., the eighth transistor T8 is an oxide thin film transistor. In an exemplary implementation, the oxide may be any one or more of following: Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Sulfur Oxide (LaCuOS), Gallium Nitride (GaN), Indium Gallium Nitride (InGaN), Aluminum Gallium Nitride (AlGaN), and Indium Gallium Aluminum Nitride (InGaAlN). In some possible implementations, the second semiconductor thin film may be made of Indium Gallium Zinc Oxide (IGZO), an electron mobility of Indium Gallium Zinc Oxide (IGZO) is higher than an electron mobility of amorphous silicon. Because the leakage current of IGZO TFT is relatively small, the eighth transistors T8 are N-type transistors, which can avoid the leakage of electricity of the first node N2 in the light emitting stage.

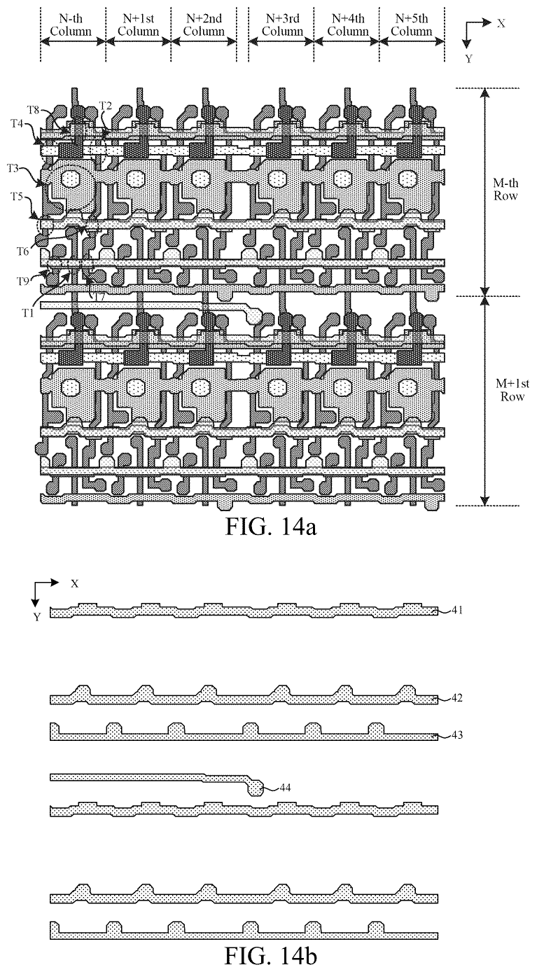

(106) A pattern of a third conductive layer is formed. In an exemplary implementation, forming the pattern of the third conductive layer may include: depositing a fifth insulation thin film and a third conductive thin film sequentially on the base substrate on which the aforementioned patterns are formed, and patterning the third conductive thin film by a patterning process to form a fifth insulation layer covering the second semiconductor layer and the pattern of the third conductive layer disposed on the fifth insulation layer, as shown in FIGS. 14a and 14b, FIG. 14a is a diagram of a planar structure of twelve sub-pixels, and FIG. 14b is a schematic plan view of the third conductive layer in FIG. 14a. In an exemplary implementation, the third conductive layer may be referred to as a third gate metal (GATE3) layer.

In an exemplary implementation, the pattern of the third conductive layer at least includes: a third scan signal line 41, a first initial signal line 42 (i.e., the first initial signal line Vinit1 in FIG. 8), a third initial signal line 43, and a secondary screen data signal connection line 44. The main body portions of the third scan signal line 41, the first initial signal line 42, the third initial signal line 43, and the secondary screen data signal connection line 44 may extend in the first direction X, and in a same sub-pixel row, the third scan signal line 41, the first initial signal line 41, and the third initial signal line 43 may be arranged sequentially in the second direction Y.

In an exemplary implementation, the secondary screen data signal connection line 44 is disposed between two adjacent rows of sub-pixels.

In an exemplary implementation, a region where the third scan signal line 41 (i.e. the fourth scan signal line S3 in FIG. 8) is overlapped with the active layer 18 of the eighth transistor T8 serves as the control electrode of the eighth transistor T8.

In an exemplary implementation, signals of the first shield line 31 and the third scan signal line 41 may be the same, i.e., the first shield line 31 and the third scan signal line 41 are connected in parallel and connected to a same signal source, so that the first shield line 31 may serve as a bottom gate electrode (i.e., a bottom control electrode) of the eighth transistor T8, forming the eighth transistor T8 with a double-gate structure.

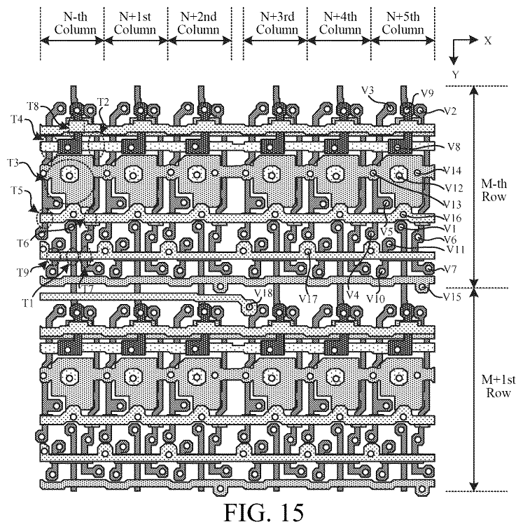

(107) A pattern of a sixth insulation layer is formed. In an exemplary embodiment, forming the pattern of the sixth insulation layer may include: depositing a sixth insulation thin film on the base substrate on which the aforementioned patterns are formed, and patterning the sixth insulation thin film through a patterning process to form a sixth insulation layer covering the third conductive layer, the sixth insulation layer being provided with a plurality of vias, as shown in FIG. 15 and FIG. 15 is a diagram of a planar structure of twelve sub-pixels.

In an exemplary implementation, the plurality of vias in each sub-pixel at least include a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, and an eighteenth via V18.

In an exemplary implementation, an orthographic projection of the first via V1 on the base substrate is located within a range of an orthographic projection of the active layer 11 of the first transistor T1 on the base substrate, and the sixth insulation layer, the fifth insulation layer, the fourth insulation layer, the third insulation layer, and the second insulation layer inside the first via V1 are etched away to expose a surface of the first region 11-1 of the active layer 11 of the first transistor T1. The first via V1 is configured so that the first electrode of the first transistor T1 subsequently formed is connected to the active layer 11 of the first transistor T1 through this via.

In an exemplary implementation, an orthographic projection of the second via V2 on the base substrate is within a range of an orthographic projection of the active layer 12 of the second transistor T2 on the base substrate, the sixth insulation layer, the fifth insulation layer, the fourth insulation layer, the third insulation layer, and the second insulation layer within the second via V2 are etched away, to expose a surface of the second region 12-2 of the active layer 12 of the first transistor T1 (also the first region 12-1 of the active layer 12 of the second transistor T2). The second via V2 is configured such that the second electrode of the first transistor T1 formed subsequently is connected with the active layer 11 of the first transistor T1 through the second via V2, and the first electrode of the second transistor T2 formed subsequently is connected with the active layer 12 of the second transistor T2 through the second via V2.

In an exemplary implementation, an orthographic projection of the third via V3 on the base substrate is within a range of an orthographic projection of the active layer 14 of the fourth transistor T4 on the base substrate, and the sixth insulation layer, the fifth insulation layer, the fourth insulation layer, the third insulation layer, and the second insulation layer within the third via V3 are etched away, to expose a surface of the first region 14-1 of the active layer 14 of the fourth transistor T4. The third via V3 is configured such that the first electrode of the fourth transistor T4 subsequently formed is connected with the active layer 14 of the fourth transistor T4 through the third via V3.

In some embodiments, an orthographic projection of the fourth via V4 on the base substrate is located within a range of an orthographic projection of the active layer 15 of the fifth transistor T5 on the base substrate, and the sixth insulation layer, the fifth insulation layer, the fourth insulation layer, the third insulation layer, and the second insulation layer within the fourth via V4 are etched away, to expose a surface of the first region 15-1 of the active layer 15 of the fifth transistor T5. The fourth via V4 is configured such that the first electrode of the fifth transistor T5 subsequently formed is connected with the active layer 15 of the fifth transistor T5 through the fourth via V6.

In an exemplary implementation, an orthographic projection of the fifth via V5 on the base substrate is within a range of an orthographic projection of the active layer T15 of the fifth transistor T5 on the base substrate, and the sixth insulation layer, the fifth insulation layer, the fourth insulation layer, the third insulation layer, and the second insulation layer within the fifth via V5 are etched away, to expose a surface of the second region 15-2 of the active layer 15 of the fifth transistor T5 (also the first region 13-1 of the active layer 13 of the third transistor T3, the second region 14-2 of the active layer 14 of the fourth transistor T4). The fifth via V5 is configured such that the second electrode of the fifth transistor T5 subsequently formed is connected with the active layer 15 of the fifth transistor T5 through the this via, and the first electrode of the third transistor T3 subsequently formed is connected with the active layer 13 of the third transistor T3 through this via, and the second electrode of the fourth transistor T4 subsequently formed is connected with the active layer 14 of the fourth transistor T4 through this via.

In an exemplary implementation, an orthographic projection of the sixth via V6 on the base substrate is within a range of an orthographic projection of the active layer 16 of the sixth transistor on the base substrate, and the sixth insulation layer, the fifth insulation layer, the fourth insulation layer, the third insulation layer, and the second insulation layer within the sixth via V6 are etched away, to expose a surface of the second region 16-2 of the active layer 16 of the sixth transistor T6 (also the second region 17-2 of the active layer 17 of the seventh transistor T7), The sixth via V6 is configured such that the second electrode of the sixth transistor T6 subsequently formed is connected with the active layer 16 of the sixth transistor T6 through this via, and the second electrode of the seventh transistor T7 subsequently formed is connected with the active layer 17 of the seventh transistor T7 through this via.

In an exemplary implementation, an orthographic projection of the seventh via V7 on the base substrate is located within a range of an orthographic projection of the active layer 17 of the seventh transistor T7 on the base substrate, and the sixth insulation layer, the fifth insulation layer, the fourth insulation layer, the third insulation layer, and the second insulation layer within the seventh via V7 are etched away, to expose a surface of the first region 17-1 of the active layer 17 of the seventh transistor T7. The seventh via V7 is configured such that the first electrode of the seventh transistor T7 subsequently formed is connected with the active layer 17 of the seventh transistor T7 through this via.

In an exemplary implementation, an orthographic projection of the eighth via V8 on the base substrate is located within a range of an orthographic projection of the active layer 28 of the eighth transistor T8 on the base substrate, and the sixth insulation layer, the fifth insulation layer within the eighth via V8 are etched away, to expose a surface of a first region 18-1 of the active layer 28 of the eighth transistor T8. The eighth via V8 is configured such that the first electrode of the eighth transistor T8 subsequently formed is connected with the active layer 18 of the eighth transistor T8 through this via.

In an exemplary implementation, an orthographic projection of the ninth via V9 on the base substrate is located within a range of an orthographic projection of the active layer 18 of the eighth transistor T8 on the base substrate, and the sixth insulation layer, the fifth insulation layer within the ninth via V9 are etched away, to expose a surface of a second region 18-2 of the active layer 18 of the eighth transistor T8. The ninth via V9 is configured such that the first electrode of the eighth transistor T8 subsequently formed is connected with the active layer 18 of the eighth transistor T8 through this via.

In an exemplary implementation, an orthographic projection of the tenth via V10 on the base substrate is located within a range of an orthographic projection of the active layer 19 of the ninth transistor T9 on the base substrate, and the sixth insulation layer, the fifth insulation layer, the fourth insulation layer, the third insulation layer, and the second insulation layer within the tenth via V10 are etched away, to expose a surface of a first region 19-1 of the active layer 19 of the ninth transistor T9. The tenth via V10 is configured such that the first electrode of the ninth transistor T9 subsequently formed is connected with the active layer 19 of the ninth transistor T9 through this via.

In an exemplary implementation, an orthographic projection of the eleventh via V11 on the base substrate is located within a range of the orthographic projection of the active layer 19 of the ninth transistor T9 on the base substrate, and the sixth insulation layer, the fifth insulation layer, the fourth insulation layer, the third insulation layer, and the second insulation layer within the eleventh via V11 are etched away, to expose a surface of a second region 19-2 of the active layer 19 of the ninth transistor T9. The eleventh via V11 is configured such that the second electrode of the ninth transistor T9 subsequently formed is connected with the active layer 19 of the ninth transistor T9 through the eleventh via V11.

In an exemplary implementation, an orthographic projection of the twelfth via V12 on the base substrate is located within a range of an orthographic projection of an opening 34 on the base substrate, and the sixth insulation layer, the fifth insulation layer, the fourth insulation layer, and the third insulation layer in the twelfth via V12 are etched away to expose a surface of the first plate 23. The twelfth via V12 is configured such that a first electrode of the eighth transistor T8 subsequently formed is connected with the first plate 23 through this via.

In an exemplary implementation, an orthographic projection of the thirteenth via V13 on the base substrate is located within a range of an orthographic projection of the second plate 33 on the base substrate, and the sixth insulation layer, the fifth insulation layer, and the fourth insulation layer within the thirteenth via V13 are etched away, to expose a surface of the second plate 33. The thirteenth via V13 is arranged such that a first electrode of the fifth transistor T5 subsequently formed is connected with the second plate 33 through this via. In an exemplary embodiment, there may be a plurality of the thirteenth via V13 served as power vias, and the plurality of thirteenth vias V13 may be sequentially arranged in the first direction X, thereby increasing the connection reliability between the first power supply line and the second plate 33.

In an exemplary implementation, the fourteenth via V14 is located within a range of an orthographic projection of the second plate 33 on the base substrate, and the sixth insulation layer, the fifth insulation layer and the fourth insulation layer within the fourteenth via V14 are etched away, to expose a surface of the second plate 33. The fourteenth via V14 is configured such that the fourth connection electrode or the first power supply adapter electrode formed subsequently is connected with the second plate 33 through this via. In an exemplary embodiment, there may be a plurality of fourteenth vias V14 which serve as power supply vias, and the plurality of fourteenth vias V14 may be sequentially arranged in the second direction Y or the first direction X, thereby increasing the reliability of the connection between the first power supply connection line and the second plate 33.

In an exemplary implementation, an orthographic projection of the fifteenth via V15 on the base substrate is located within a range of an orthographic projection of the second power supply signal connection line 32 on the base substrate, and the sixth insulation layer, the fifth insulation layer and the fourth insulation layer within the fifteenth via V15 are etched away, to expose a surface of the second power supply connection line 32. The fifteenth via V15 is configured such that the second power supply signal line formed subsequently is connected with the second power supply connection line 32 through this via.

In an exemplary implementation, an orthographic projection of the sixteenth via V16 on the base substrate is located within a range of an orthographic projection of the first initial signal line 42 on the base substrate, and the sixth insulation layer within the sixteenth via V16 are etched away, to expose a surface of the first initial signal line 42. The sixteenth via V16 is configured such that the first electrode of the first transistor T1 subsequently formed is connected with the first initial signal line 42 through this via.

In an exemplary implementation, an orthographic projection of the seventeenth via V17 on the base substrate is within a range of an orthographic projection of the third initial signal line 43 on the base substrate, and the sixth insulation layer within the seventeenth via V17 is etched away, to expose a surface of the third initial signal line 43. The seventeenth via V17 is configured such that the first electrode of the first transistor T9 subsequently formed is connected with the third initial signal line 43 through this via.

In an exemplary implementation, an orthographic projection of the eighteenth via V18 on the base substrate is located within a range of an orthographic projection of the secondary screen data signal connection line 44 on the base substrate, and the sixth insulation layer within the eighteenth via V18 is etched away, to expose a surface of the secondary screen data signal connection line 44. The eighteenth via V18 is configured such that the main screen data signal line formed subsequently is connected with the secondary screen data signal connection line 44 through this via.

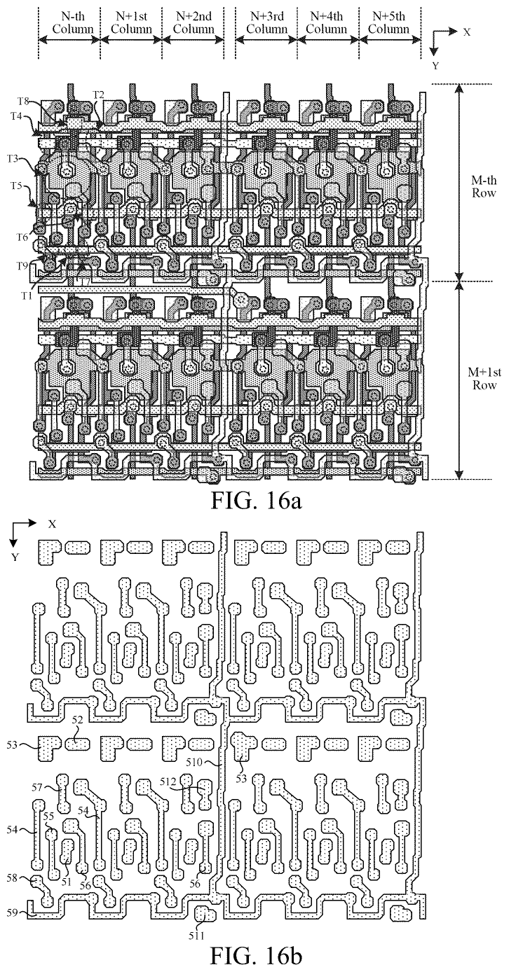

(108) A pattern of a fourth conductive layer is formed. In an exemplary embodiment, forming the fourth conductive layer may include: depositing a fourth conductive thin film on the base substrate on which the aforementioned patterns are formed, and patterning the fourth conductive thin film by a patterning process, to form the fourth conductive layer disposed on the sixth insulation layer, as shown in FIG. 16a and FIG. 16b, FIG. 16a is a diagram of a planar structure of twelve sub-pixels, and FIG. 16b is a planar schematic view of the fourth conductive layer in FIG. 16a. In an exemplary implementation, the fourth conductive layer may be referred to as a first source drain metal (SD1) layer.

In an exemplary implementation, the fourth conductive layer at least includes: a first connection electrode 51, a second connection electrode 52, a third connection electrode 53, a fourth connection electrode 54, a fifth connection electrode 55, a sixth connection electrode 56, a seventh connection electrode 57, an eighth connection electrode 58, a second initial signal line 59 (i.e., the second initial signal line Vinit2 in FIG. 8), a second initial signal connection line 510, a second power supply adapter electrode 511 and a first power supply adapter electrode 512.

In an exemplary implementation, the first connection electrode 51 may be in a shape of a strip whose main body portion extends in the second direction Y, and the first connection electrode 51 is connected with the first region 11-1 of the active layer 11 of the first transistor T1 through the first via V1 and connected with the first initial signal line 42 in sub-pixels in a row through the sixteenth via V16 in that sub-pixel row. In an exemplary embodiment, the first connection electrode 51 may serve as the first electrode of the first transistor T1, and the first connection electrode 51 is configured to be connected with the first initial signal line 42 and the active layer 21 of the first transistor T1.

In an exemplary implementation, the main body portion of the second connection electrode 51 extends in the first direction X, a first end of the second connection electrode 52 is connected with the second region 11-2 of the active layer 11 of the first transistor T1 (also the first region 12-1 of the active layer 12 of the second transistor T2) through the second via V2, and a second end of the second connection electrode 52 is connected with the second region 18-2 of the active layer 18 of the eighth transistor T8 through the ninth via V9, so that the second electrode of the first transistor T1, the first electrode of the second transistor T2, and the second electrode of the eighth transistor T8 have a same potential. In an exemplary embodiment, the second connection electrode 52 may serve as the second electrode of the first transistor T1, the first electrode of the second transistor T2 and the second electrode of the eighth transistor T8.

In an exemplary implementation, the third connection electrode 53 is connected with the first region 14-1 of the active layer 142 of the fourth transistor T4 through the third via V3. In an exemplary embodiment, the third connection electrode 53 may serve as the first electrode of the fourth transistor T4. In an exemplary embodiment, the third connection electrode 53 may also be connected with the secondary screen data signal connection line 44 through the eighteenth via V18; in an exemplary implementation, in a same sub-pixel row, not every third connection electrode 53 is connected with the secondary screen data signal connection line 44, for example, one of the plurality of third connection electrodes 53 of a row of sub-pixels is connected with the secondary screen data signal connection line 44.

In an exemplary implementation, a shape of the fourth connection electrode 54 may be a shape of a strip or a polyline extending in the second direction Y, one end of the fourth connection electrode 54 may be connected with the first region 15-1 of the active layer 15 of the fifth transistor T5 through the fourth via V4, and the other end may be connected with the second plate 33 of the capacitor through the thirteenth via V13. In an exemplary embodiment, the fourth connection electrode 54 may serve as the first electrode of the fifth transistor T5. In an exemplary implementation, the fourth connection electrode 54 may be configured to be electrically connected with a first power supply line formed subsequently. Among the plurality of fourth connection electrodes 54 in a row of sub-pixels, not each fourth connection electrode 54 is connected with the first power supply line formed subsequently. For example, one pixel unit includes 3 sub-pixels, fourth connection electrodes 54 of two sub-pixels in one pixel unit may be connected with the first power supply line formed subsequently, and a fourth connection electrode 54 in the other sub-pixel may not be connected with the first power supply line formed subsequently.

In an exemplary implementation, the fifth connection electrode 55 may be in a shape of a strip extending in the second direction Y, the fifth connection electrode 55 is connected with the second region 15-2 of the active layer 15 of the fifth transistor T5 (also the second region 14-2 of the fourth transistor T4) through the fifth via V5, and the fifth connection electrode 55 is connected with the second region 19-2 of the ninth transistor T9 through the eleventh via V11. In an exemplary embodiment, the fifth connection electrode 55 may serve as a second electrode of the fifth transistor T5, a second electrode of the ninth transistor T9, and a second electrode of the fourth transistor T4.

In an exemplary implementation, the sixth connection electrode 56 may be in a shape of a strip or a polyline extending in the second direction Y, and the sixth connection electrode 56 is connected with the second region 16-2 of the active layer 26 of the sixth transistor T6 (also the second region 17-2 of the active layer 17 of the seventh transistor T7) through the sixth via V6. In an exemplary embodiment, the sixth connection electrode 56 may serve as the second electrode of the sixth transistor T6 and the second electrode of the seventh transistor T7, and the sixth connection electrode 56 is configured to be connected with an anode connection electrode of the light emitting element formed subsequently.

In an exemplary implementation, the seventh connection electrode 57 may be in a shape of a strip or a polyline extending in the second direction Y, and one end of the seventh connection electrode 57 is connected with the first region 18-1 of the active layer 18 of the eighth transistor T8 through the eighth via V8, and the other end is connected with the first plate 23 through the twelfth via V12. In an exemplary implementation, the seventh connection electrode 57 may serve as the first electrode of the eighth transistor T8.

In an exemplary implementation, the eighth connection electrode 58 may be in a polyline extending in the second direction Y, one end of the eighth connection electrode 58 may be connected with the first region 19-1 of the active layer 19 of the ninth transistor T9 through the tenth via V10, and the other end may be connected with the third initial signal line 43 through the seventeenth via V16. In an exemplary implementation, the eighth connection electrode 58 may serve as the first electrode of the ninth transistor T9.

In an exemplary implementation, the second initial signal line 59 may be in a shape of a polyline whose main body portion extends in the first direction X, and the second initial signal line 59 is connected with the first regions 17-1 of the active layers 17 of a plurality of seventh transistors T7 through a plurality of seventh vias V7 in a row of sub-pixels, to write an initial voltage into the plurality of seventh transistors T7 in the row of sub-pixels. In an exemplary embodiment, because the second initial signal line 59 is connected with the first regions 17-1 of the active layers 27 of all seventh transistors T7 in a row of sub-pixels, the first electrodes of all seventh transistors T7 in a row of sub-pixels may be ensured to have a same potential, which is beneficial to improving uniformity of the panel, avoiding display defect of the display substrate, and ensuring the display effect of the display substrate. In an exemplary embodiment, the second initial signal line 59 may serve as the first electrode of the seventh transistor T7. In an exemplary implementation, in a row of sub-pixels, the second initial signal line 59 may be bent to bypass the eighth connection electrode 58 adjacent in the second direction Y, for example, the second initial signal line 59 may be bent to bypass from one side of the eighth connection electrode 58 in the second direction Y.

In an exemplary implementation, the second initial signal connection line 510 may be a shape of a polyline or a strip whose main body portion extends in the second direction Y, and both ends of the second initial signal connection line 510 are respectively connected with two adjacent second initial signal lines 59. In the second direction Y, the second initial signal connection line 510 are located between the two adjacent second initial signal lines 59. In an exemplary embodiment, the second initial signal connection line 510 and the second initial signal line 59 may form an integrated structure. In an exemplary embodiment, by a plurality of second initial signal connection lines 510, a plurality of second initial signal lines 59 arranged in the second direction Y are connected into an integral grid-like structure, so that the plurality of second initial signal lines 59 have a same potential, which is beneficial to improving the display uniformity of the display panel, avoiding poor display of the display substrate, improving low gray-scale image quality, and ensuring the display effect of the display substrate. In an exemplary embodiment, a second initial signal connection line 510 may be disposed between two adjacent columns of sub-pixels or between two adjacent columns of pixel units (one pixel unit may include at least three sub-pixels sequentially arranged in the first direction X in a row of sub-pixels). For example, as shown in FIG. 16b, one pixel unit includes three sub-pixels sequentially arranged in a row of sub-pixels. A plurality of pixel units are arranged in an array. A second initial signal connection line 510 may be disposed between two adjacent pixel units. A second initial signal connection line 510 may be disposed between the N+2nd and N+3rd columns of sub-pixels. Spacing between the two adjacent second initial signal connection lines 510 may be separated by three columns of sub-pixels.

In an exemplary implementation, the second power supply adapter electrode 511 may be connected with the second power supply connection line 32 through the fifteenth via V15, and the second power supply adapter electrode 511 may be configured to be connected with the second power supply line formed subsequently. In an exemplary implementation, instead of the second power adapter electrode 511 being in each sub-pixel, for example, in a same row of sub-pixels, three sub-pixels sequentially arranged in the first direction X form a pixel unit, and the second power supply adapter electrode 511 may be disposed in each pixel unit. In an exemplary implementation, in a row of sub-pixels, the second initial signal line 59 may be bent to bypass the second power adapter electrode 511 adjacent in the second direction Y. For example, the second initial signal line 59 may be bent to bypass from a side of the second power supply adapter electrode 511 in an opposite direction of the second direction Y.

In an exemplary implementation, the first power supply adapter electrode 512 may be connected with the second plate 33 through the fourteenth via V14, and the first power supply adapter electrode 512 may be configured to be connected with a first power supply line formed subsequently. In an exemplary implementation, the first power supply adapter electrode 512 is disposed in some of the sub-pixels, and not each sub-pixel is provided with the first power supply adapter electrode 512; for example, among an N-th column of sub-pixels to an N+5th column of sub-pixels, an N+2nd column of sub-pixels and the N+5th column of sub-pixels are provided with the first power supply adapter electrode 512, the N-th column of sub-pixels, an N+1st column of sub-pixels, an N+3rd column of sub-pixels and an N+4th column of sub-pixels are not provided with the first power supply adapter electrode 512, the fourth connection electrodes 54 in the N-th column of sub-pixels, the N+1st column of sub-pixels, the N+3rd column of sub-pixels and the N+4th column of sub-pixel are electrically connected with the first power supply line formed subsequently, and the fourth connection electrodes 54 in the N+2nd column of sub-pixels and the N+5th column of sub-pixels are not electrically connected with the first power supply line formed subsequently.

In an exemplary implementation, in a same row of sub-pixels, in the case that the second initial signal line 59 is not disposed at a position between adjacent two columns of sub-pixels, one end of the fourth connection electrode 54 is connected with the active layer 15 of the fifth transistor T5 and the second plate 32 in one column of sub-pixels, and the other end extends into an adjacent column of sub-pixels, and is electrically connected with the first power supply line formed subsequently; in the case where the second initial signal line 59 is disposed at a position between the two adjacent columns of sub-pixels, the fourth connection electrode 54 is connected with the active layer 15 of the fifth transistor T5 and the second plate 32 in one of the columns of sub-pixels, and does not extend into an adjacent column of sub-pixels, which are electrically connected with the first power supply line formed subsequently through the first power supply adapter electrode 512.

In an exemplary implementation, in the first direction X, the first power supply adapter electrode 512 is located on one side of the second initial signal line 59, and the fourth connection electrode 54 is located on the other side of the second initial signal line 59. In an exemplary implementation, the fourth connection electrode 54 adjacent to the second initial signal line 59 may have a strip structure in shape, and not be electrically connected with the first power supply line formed subsequently, and the fourth connection electrode 54 not adjacent to the second initial signal line 59 may have a polyline structure in shape, one end of the fourth connection electrode 54 is connected with the active layer 15 of the fifth transistor T5 in one column of sub-pixels, and the other end is located in the adjacent column of sub-pixels and is electrically connected with the first power supply line formed subsequently in that column of sub-pixels.

(109) Patterns of a seventh insulation layer and a first planarization layer are formed. In an exemplary embodiment, forming the patterns of the seventh insulation layer and the first planarization layer may include: first depositing a seventh insulation thin film on the base substrate on which the aforementioned patterns are formed, then coating a first planarization thin film, patterning the first planarization thin film and the seventh insulation thin film by using a patterning process, to form a seventh insulation layer covering the pattern of the fourth conductive layer and a first planarization layer disposed on the seventh insulation layer, the seventh insulation layer and the first planarization layer being provided with a plurality of vias, as shown in FIG. 17, and FIG. 7 is a planar structure view of twelve sub-pixels.

In an exemplary implementation, the plurality of vias in each sub-pixel at least include a nineteenth via V19, a twentieth via V20, a twenty-first via V21, a twenty-second via V22, and a twenty-third via V23.

In an exemplary implementation, an orthographic projection of the nineteenth via V19 on the base substrate is within a range of an orthographic projection of the third connection electrode 53 on the base substrate. The first planarization layer and the seventh insulation layer within the nineteenth via V19 are etched away, to expose a surface of the third connection electrode 53. The nineteenth via V19 is configured such that the main screen data signal line formed subsequently is connected with the third connection electrode 53 through this via.

In an exemplary implementation, an orthographic projection of the twentieth via V20 on the base substrate is within a range of an orthographic projection of a sixth connection electrode 56 on the base substrate. The first planarization layer and the seventh insulation layer within the twentieth via V20 are etched away, to expose a surface of the sixth connection electrode 56. The twentieth via V20 is configured such that an anode connection electrode of a light emitting element formed subsequently is electrically connected with the sixth connection electrode 56 through this via.

In an exemplary implementation, an orthographic projection of the twenty-first via V21 on the base substrate is located within a range of an orthographic projection of the fourth connection electrode 54 on the base substrate. The first planarization layer and the seventh insulation layer within the twenty-first via V21 are etched away, to expose a surface of the fourth connection electrode 54. The twenty-first via V21 is configured such that the first power supply line formed subsequently is connected with the fourth connection electrode 54 through this via.

In an exemplary implementation, an orthographic projection of the twenty-second via V22 on the base substrate is located within a range of an orthographic projection of the second connection electrode 511 on the base substrate. The first planarization layer and the seventh insulation layer within the twenty-second via V22 are etched away, to expose a surface of the second power supply adapter electrode 511. The twenty-second via V22 is configured such that the second power supply line formed subsequently is connected with the second power supply adapter line 511 through this via.

In an exemplary implementation, an orthographic projection of the twenty-third via V23 on the base substrate is within a range of an orthographic projection of a first power supply adapter electrode 512 on the base substrate. The first planarization layer and the seventh insulation layer within the twenty-third via V23 are etched away, to expose a surface of the first power supply adapter electrode 512. The twenty-third via V23 is configured such that the first power supply line subsequently formed is connected with the first power supply adapter electrode 512 through this via.

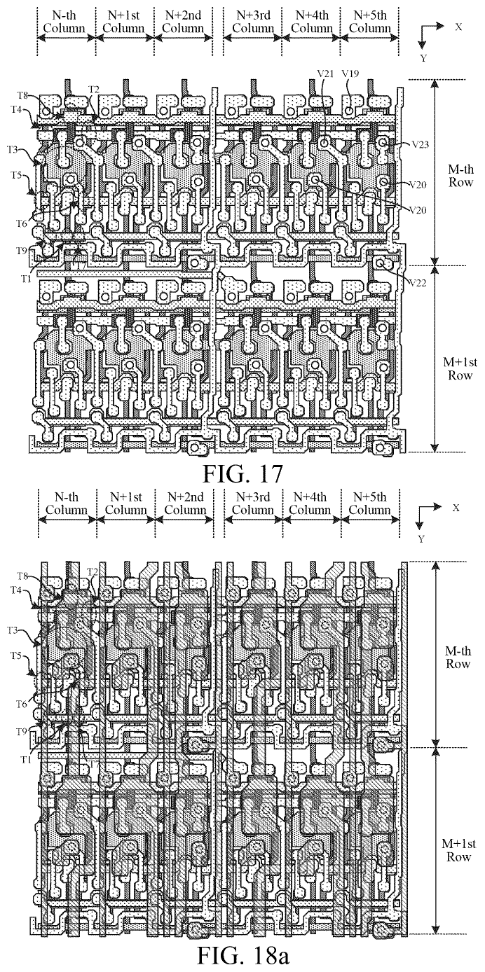

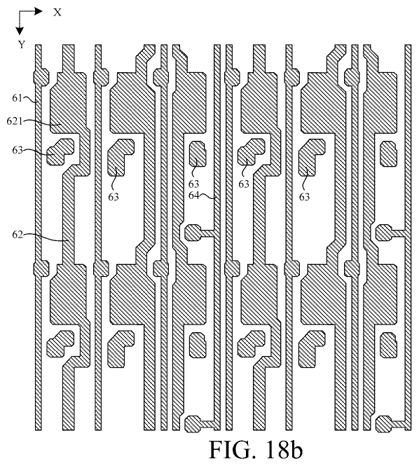

(110) Forming a pattern of a fifth conductive layer. In an exemplary embodiment, forming the fifth conductive layer may include: depositing a fifth conductive thin film on the base substrate on which the aforementioned patterns are formed, and patterning the fifth conductive thin film by using a patterning process to form the fifth conductive layer disposed on the first planarization layer, as shown in FIG. 18a to FIG. 18b, FIG. 18a is a planar structure view of twelve sub-pixels, and FIG. 18b is a planar schematic view of the fifth conductive layer in FIG. 18a. In an exemplary implementation, the fifth conductive layer may be referred to as a second source-drain metal (SD2) layer.

In an exemplary embodiment, the fifth conductive layer at least includes a data signal line 61 (i.e., the data signal line D in FIG. 8), a first power supply line 62 (i.e., the first power supply line VDD in FIG. 8), a anode connection electrode 63, and a second power supply line 64. In an exemplary embodiment, the anode connection electrode 63 is an anode connection electrode of a light emitting element.

In an exemplary embodiment, the data signal line 61 may be in a shape of a strip or a polyline whose main body portion extends in the second direction Y, and the data signal line 61 is connected with the third connection electrode 53 through the nineteenth via V19. Since the third connection electrode 53 is connected with the first region 14-1 of the active layer 14 of the fourth transistor T4 through a via, it is achieved that the data signal line 61 is connected with the first electrode of the fourth transistor T4 and a data signal is written into the fourth transistor T4.

In an exemplary embodiment, the first power supply line 62 is in a shape of a polyline whose main body portion extends in the second direction Y, and the first power supply line 62 is connected with the fourth connection electrode 54 or the first power supply adapter electrode 512 through the twenty-first via V21. Because the fourth connection electrode 54 and the first power supply adapter electrode 512 are connected with the second plate 33 through the via, it is achieved that the first power supply line 62 is connected with the second plate 33 and a power supply signal is written into the second plate 33. Because the fourth connection electrode 54 is connected with the first region 15-1 of the active layer 15 of the fifth transistor T5 through the via, it is achieved that the first power supply line 62 is connected with the first electrode of the fifth transistor T5 and a power supply signal is written into the fifth transistor T5. In an exemplary embodiment, the first power supply line 62 may be bent to bypass the anode connection electrodes 63 adjacent in the first direction X. For example, in a row of sub-pixels, one pixel unit may include three sub-pixels sequentially arranged in the first direction X, in a same pixel unit, the first power supply line 62 in the first and second sub-pixels may be bent to bypass from one side of the anode connection electrode 63 in the first direction X, and the first power supply line 62 in the third sub-pixel may be bent to bypass from one side of the anode connection electrode 63 in an opposite direction of the first direction X. In an exemplary embodiment, in one sub-pixel, a size of the first power supply line 62 in the first direction X on a side of the anode connection electrode 63 close to the storage capacitor (i.e., on a side of the anode connection electrode 63 in the opposite direction of the second direction Y) is greater than a size of the first power supply line 62 in the first direction X on a side of the anode connection electrode 63 away from the storage capacitor (i.e., on a side of the anode connection electrode 63 in the second direction Y). For example, the first power supply line 62 may be provided with a plurality of bumps 621, and sizes of the bumps 621 in the first direction X on the first power supply line 62 are greater than sizes of the bumps 621 in the first direction X on both sides of the bumps 621 in the second direction Y.

In an exemplary embodiment, a plurality of columns of first power supply lines 62 and the second plates 33 of a plurality of sub-pixels (a plurality of second plates 33 in a same row of sub-pixels are connected to each other) are electrically connected to form a grid-like shape, so that the plurality of first power supply lines 62 in the display substrate have substantially a same potential, which is beneficial to improving the uniformity of the panel, avoiding poor display of the display substrate, and ensuring the display effect of the display substrate.

In an exemplary embodiment, the anode connection electrode 63 is connected with the sixth connection electrode 56 through the twentieth via V20. Because the sixth connection electrode 56 is connected to the second region 16-2 (it is also the second region 17-2 of the active layer 17 of the seventh transistor T7) of the active layer 16 of the sixth transistor T6 through a via, connections between the anode connection electrode 63 and the second electrode of the sixth transistor T6 as well as the second electrode of the seventh transistor T7 are achieved.

In an exemplary embodiment, the second power supply line 64 may be in a shape of a strip extending in the second direction Y, the second power supply line 64 may be provided with a connection structure 641, and the connection structure 641 on the second power supply line 64 may be connected with the second power supply adapter electrode 511 through the twenty-second via V22. Since the second power supply adapter electrode 511 is connected with the second power supply connection line 32 through the via, it is achieved that the second power supply line 64 is connected with the second power supply connection line 32. The plurality of columns of the second power supply line 64 and the plurality of rows of the second power supply connection line 32 are electrically connected to form a grid shape, and it can enable the second power supply lines 64 in the display substrate to have substantially a same potential, which is beneficial to improving the uniformity of the panel and ensuring the display effect of the display substrate.

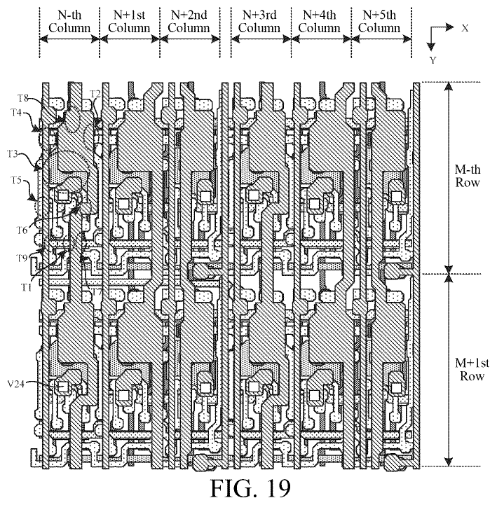

(111) A pattern of a second planarization layer is formed. In an exemplary embodiment, forming the pattern of the second planarization layer may include: coating a second planarization thin film on the base substrate on which the aforementioned patterns are formed, patterning the second planarization thin film by using a patterning process, to form a second planarization layer covering the pattern of the fifth conductive layer, the second planarization layer is provided with a plurality of vias, as shown in FIG. 19, and FIG. 19 is a planar structure diagram of twelve sub-pixels.

In an exemplary implementation, the plurality of vias at least include a twenty-fourth via V24.

In an exemplary implementation, a via of each sub-pixel at least includes a twenty-fourth via V24. An orthographic projection of the twenty-fourth via V24 on the base substrate is within a range of an orthographic projection of the anode connection electrode 63 on the base substrate. The second planarization layer within the twenty-fourth via V24 is etched away, to expose a surface of the anode connection electrode 63. The twenty-fourth via V24 is configured such that an anode formed subsequently is electrically connected with the anode connection electrode 63 through this via. In an exemplary implementation, the twenty-fourth via V24 may be referred to as an anode via.

So far, a drive circuit layer has been manufactured on the base substrate. In an exemplary implementation, in a plane perpendicular to the display substrate, the drive circuit layer may include a first semiconductor layer, a first conductive layer, a second conductive layer, a second semiconductor layer, a third conductive layer, a fourth conductive layer and a fifth conductive layer sequentially stacked on the base substrate.

In an exemplary implementation, the drive circuit layer may include a first insulation layer disposed between the base substrate and the first semiconductor layer, a second insulation layer disposed between the first semiconductor layer and the first conductive layer, a third insulation layer disposed between the first conductive layer and the second conductive layer, a fourth insulation layer disposed between the second conductive layer and the second semiconductor layer, a fifth insulation layer disposed between the second semiconductor layer and the third conductive layer, a sixth insulation layer disposed between the third conductive layer and the fourth conductive layer, a seventh insulation layer and a first planarization layer disposed between the fourth conductive layer and the fifth conductive layer, a second planarization layer disposed between the fifth conductive layer.

In an exemplary embodiment, after the preparation of the drive circuit layer is completed, a light emitting structure layer is prepared on the drive circuit layer, and the preparation process of the light emitting structure layer may include the following operations: forming an anode pattern (i.e., an anode conductive layer), and the anode is connected with the anode connection electrode through an anode via (i.e., a twenty-fourth via V24); forming a pixel definition layer, a pixel opening being disposed on the pixel definition layer, and the pixel opening exposes an anode; using an evaporation or inkjet printing process to form an organic light emitting layer, the organic light emitting layer being connected with an anode through a pixel opening, and a cathode being formed on the organic light emitting layer; forming an encapsulation layer that may include a first encapsulation layer, a second encapsulation layer and a third encapsulation layer stacked, wherein the first encapsulation layer and the third encapsulation layer may be made of an inorganic material, the second encapsulation layer may be made of an organic material, and the second encapsulation layer is disposed between the first encapsulation layer and the third encapsulation layer, so as to ensure that external water vapor cannot enter the light emitting structure layer. The steps of forming the anode conductive layer and the pixel definition layer are as follows:

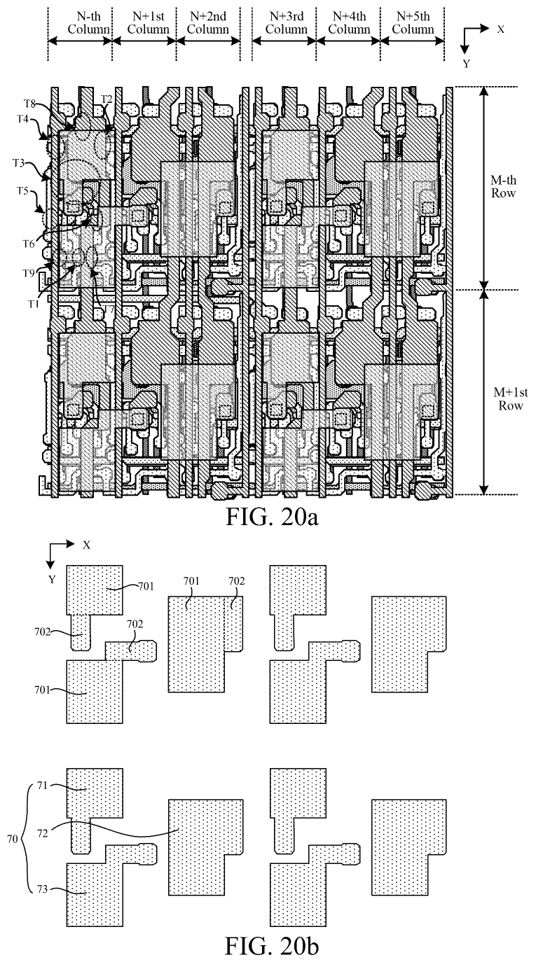

(112) A pattern of an anode conductive layer is formed. In an exemplary implementation, forming the pattern of the anode conductive layer may include: depositing an anode conductive thin film on the base substrate on which the aforementioned patterns are formed, and patterning the anode conductive thin film by using a patterning process, to form the pattern of the anode conductive layer disposed on the planarization layer, as shown in FIG. 20a to FIG. 20b, FIG. 20a is a schematic diagram of a planar structure of twelve sub-pixels, and FIG. 20b is a planar schematic diagram of the anode conductive layer in FIG. 22A.

In an exemplary implementation, the pattern of the anode conductive layer may at least include a plurality of anodes 70, and the plurality of anodes 70 may include a first anode 71 of a red light emitting unit, a second anode 72 of a blue light emitting unit, and a third anode 73 of a green light emitting unit. A region where the first anode 71 is located may form a red light emitting unit that emits red light, a region where the second anode 72 is located may form a blue light emitting unit that emits blue light, and a region where the third anode 73 is located may form a green light emitting unit that emits green light.

In an exemplary implementation, the first anode 71, the second anode 72, and the third anode 73 may be connected with the anode connection electrodes 63 in a corresponding sub-pixel through the twenty-fourth vias V24. Since the anode connection electrode 63 in the sub-pixel is electrically connected with the second electrode of the sixth transistor T6 (also the second electrode of the seventh transistor T7) through the via, the first anode 71, the second anode 72 and the third anode 73 can be connected with the second electrode of the sixth transistor T6 and the second electrode of the seventh transistor T7 through the anode connection electrode 63, respectively, thereby realizing that the pixel drive circuit drives the light emitting device to emit light.

In an exemplary implementation, the anode 70 may include an anode main body portion 701 and an anode connection portion 702, the anode main body portion 701 may have a rectangular structure, one end of the anode connection portion 702 is connected with the anode main body portion 701, and the other end of the anode connection portion 702 is electrically connected with the anode connection electrode 63 through the twenty-fourth via V24. The anode connection portion 702 may have a strip structure, and the anode connection portion 702 may be disposed to compensate for the difference of the parasitic capacitance caused by the signal wiring between the plurality of sub-pixels. By disposing the anode connection portion 702, the parasitic capacitance of the plurality of sub-pixels can be kept consistent, and the display uniformity of the display substrate can be improved.

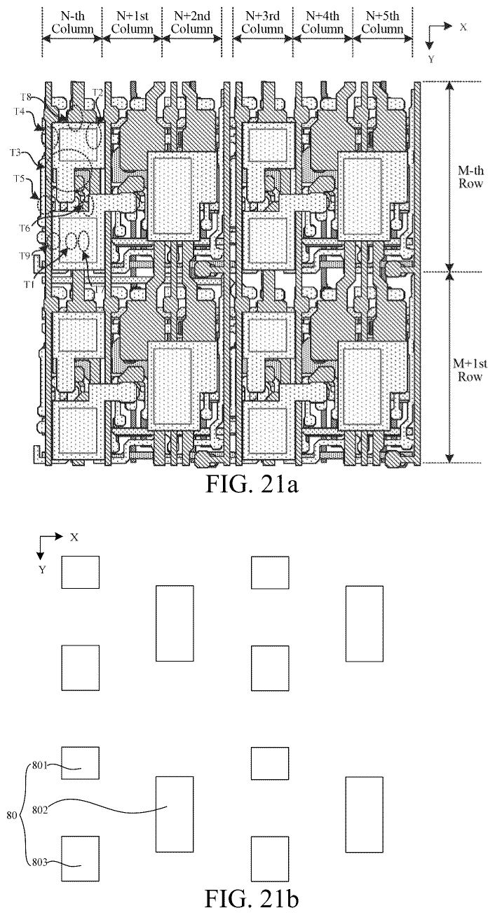

(113) A pattern of a pixel definition layer is formed. In an exemplary implementation, forming the pattern of the pixel definition layer may include: depositing a pixel definition layer thin film on the base substrate on which the aforementioned patterns are formed, patterning the pixel definition layer by using a patterning process, to form the pattern of the pixel definition layer disposed on an anode conductive layer, as shown in FIG. 21a to FIG. 21b, FIG. 21a is a schematic diagram of a planar structure of twelve sub-pixels, and FIG. 21b is a schematic diagram of a planar structure of the pixel definition layer in FIG. 21a.

In an exemplary implementation, the pattern of the pixel definition layer may include multiple pixel openings 80, and the pixel opening exposes an anode 70. In an exemplary implementation, an orthographic projection of a pixel opening on the base substrate is located within a range of an orthographic projection of an anode 70 on the base substrate. In an exemplary implementation, the pixel opening 80 may include a pixel opening 801 of a first sub-pixel, a pixel opening 802 of a second sub-pixel, and a pixel opening 803 of a third sub-pixel, wherein there is an overlapping area where an orthographic projection of the pixel opening 801 of the first sub-pixel on the base substrate is overlapped with an orthographic projection of the first anode 71 on the base substrate; there is an overlapping area where an orthographic projection of the pixel opening 802 of the second sub-pixel on the base substrate is overlapped with an orthographic projection of the second anode 72 on the base substrate; there is an overlapping area where an orthographic projection of the pixel opening 803 of the third sub-pixel on the base substrate is overlapped with an orthographic projection of the third anode 73 on the base substrate.

In an exemplary implementation, the pixel opening 802 and the second anode 72 in the second sub-pixel are overlapped with a pattern of at least two portions of the signal lines in at least one conductive layer in the drive circuit layer, and a pattern of the at least two portions of signal lines are distributed on both sides of a center of the pixel opening 802 of the second sub-pixel, so that an anode flatness of each area in one second sub-pixel can be as consistent as possible, and anode flatnesses of a plurality of second sub-pixels can be as consistent as possible, thereby improving the display uniformity of the display substrate.

In an exemplary implementation, a main body portion of the pattern of the at least two portions of signal lines extends in the column direction Y, as shown in FIG. 18b, the pattern of the at least two portions of signal lines of the at least one conductive layer in the drive circuit layer may include a main screen data signal line 61, the main screen data signal line 61 may extend in the column direction Y, in the column direction Y, the main screen data signal line 611 may be distributed on both sides of a center of the pixel opening 802 of the second sub-pixel (that is, in the column direction Y, a region where the main screen data signal line 61 is overlapped with the pixel opening 802 of the second sub-pixel may be symmetrical with respect to a midline extending in the row direction X), and in the row direction X, the main screen data signal line 61 may be distributed on both sides of the center of the pixel opening 802 of the second sub-pixel (that is, in the row direction X, the region where the same main screen data signal line 61 is overlapped with the pixel opening 802 of the second sub-pixel may be symmetrical with respect to the midline extending in the column direction Y).

In an exemplary implementation, as shown in FIG. 18b, the at least two parts of the signal line pattern may further include a first power supply line 62, in the column direction Y, the two first power supply lines 62 may be distributed on both sides of the center of the pixel opening 802 of the second sub-pixel (i.e., in the column direction Y, the area where the two first power supply lines 72 and the pixel opening 802 of the second sub-pixel overlap may be on both sides of the center of the pixel opening 802 of the second sub-pixel extending in the row direction X), and in the row direction X, the first power supply line 72 may be distributed on both sides of the center of the pixel opening 802 of the second sub-pixel (i.e., in the row direction X, the area where the same first power supply line 72 and the pixel opening 802 of the second sub-pixel overlap may be on both sides of the midline of the pixel opening 802 of the second sub-pixel extending in the column direction Y, and the area where the first power supply line 62 and the pixel opening 802 of the second sub-pixel overlap may be on both sides of the main screen data signal line 61).

In an exemplary implementation, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo and Ti/Al/Ti. The first insulation layer, the second insulation layer, the third insulation layer, the fourth insulation layer, the fifth insulation layer, the sixth insulation layer, and the seventh insulation layer may be made of any one or more of silicon oxide (SiOx), silicon nitride (SiNx), and silicon oxynitride (SiON), and may be single layers, multiple layers, or composite layers. The first insulation layer may be referred to as a Buffer layer, which is used for improving the water and oxygen resistance of the base substrate. The second insulation layer, the third insulation layer, the fourth insulation layer, and the fifth insulation layer may be referred to as a gate insulation (GI) layer, the sixth insulation layer may be referred to as an interlayer dielectric (ILD) layer, and the seventh insulation layer may be referred to as a passivation (PVX) layer.

The structure and preparation process shown in the aforementioned embodiments of the present disclosure are only an exemplary explanation. In an exemplary implementation, the corresponding structure can be changed and the patterning process can be increased or reduced according to actual needs. The display substrate of an embodiment of the present disclosure may be applied to other display devices with a pixel drive circuit, such as a quantum dot display. The present disclosure is not limited herein.

The present disclosure further provides a display apparatus, including the display substrate according to any of the aforementioned embodiments. The display apparatus may be any product or component with a display function, such as a wearable device (a watch), a mobile phone, a tablet computer, a television, a display, a laptop computer, a digital photo frame, a navigator and the like.

An embodiment of the present disclosure further provides a display apparatus including the display substrate including the first opening described above. The display apparatus may further include a photosensitive element, and an orthographic projection of the photosensitive element on the base substrate of the display substrate is within a range of an orthographic projection of the first opening of the display substrate on the base substrate.

In a display substrate provided by an embodiment of the present disclosure, there is an overlapping area where a pixel opening of at least one sub-pixel in the display substrate is overlapped with orthographic projections of at least part of signal lines in at least one conductive layer on the base substrate, and in the at least one sub-pixel, an overlapping area corresponding to one sub-pixel is symmetrical with respect to an orthographic projection of at least one midline of the pixel opening of that sub-pixel on the base substrate, so that the technical problem of the color cast with the large viewing angle in the display substrate can be solved.

The embodiments of the present disclosure, that is, features in the embodiments, may be combined with each other to obtain a new embodiment in a situation of no conflicts.

Although the implementations disclosed in the embodiments of the present disclosure are described above, contents are only implementations for facilitating understanding of the embodiments of the present disclosure, but are not intended to limit the embodiments of the present disclosure. Any person skilled in the art to which the embodiments of the present disclosure pertain may make any modifications and variations in forms and details of implementation without departing from the spirit and the scope disclosed in the embodiments of the present disclosure. Nevertheless, the scope of patent protection of the embodiments of the present disclosure shall still be subject to the scope defined by the appended claims.

1. A display substrate comprising a base substrate and a plurality of sub-pixels, a drive circuit layer and a pixel definition layer disposed on the base substrate, wherein the drive circuit layer is located between the base substrate and the pixel definition layer in a direction perpendicular to a plane on which the display substrate is located, a plurality of pixel openings are formed in the pixel definition layer, each sub-pixel comprises at least one pixel opening, and the drive circuit layer comprises a plurality of conductive layers;
there are overlapping areas between an orthographic projection of a pixel opening of at least one sub-pixel on the base substrate and orthographic projections of at least part of signal lines in at least one conductive layer on the base substrate; in the at least one sub-pixel, an overlapping area corresponding to one sub-pixel is symmetrical with respect to an orthographic projection of at least one midline of a pixel opening of the one sub-pixel on the base substrate.

2. The display substrate according to claim 1, wherein at least part of the conductive layers comprise a conductive layer nearest to the pixel definition layer in the drive circuit layer in the direction perpendicular to the plane on which the display substrate is located.

3. The display substrate according to claim 2, wherein the conductive layer nearest to the pixel definition layer in the drive circuit layer comprises a first power supply line, the plurality of sub-pixels comprise multiple types of sub-pixels, and the multiple types of sub-pixels comprise a first sub-pixel, a second sub-pixel and a third sub-pixel;
both an area of an overlapping area where an orthographic projection of a pixel opening of the first sub-pixel on the base substrate is overlapped with an orthographic projection of a first power supply line on the base substrate and an area of an orthographic projection of an overlapping area where a pixel opening of the second sub-pixel on the base substrate is overlapped with the orthographic projection of the first power supply line on the base substrate are greater than an area of an overlapping area where an orthographic projection of a pixel opening of the third sub-pixel on the base substrate is overlapped with the orthographic projection of the first power supply line on the base substrate.

4. The display substrate according to claim 3, wherein the conductive layer nearest to the pixel definition layer in the drive circuit layer further comprises data signal lines, wherein there are overlapping areas where the orthographic projection of the pixel opening of the second sub-pixel on the base substrate is overlapped with orthographic projections of two first power supply lines and one data signal line adjacent to the pixel opening of the second sub-pixel on the base substrate, and in a direction parallel to the plane on which the display substrate is located, the first power supply lines and the data signal line extend in a second direction, and the two first power supply lines are respectively located on both sides of the one data signal line in a first direction, wherein the first direction intersects with the second direction.

5. The display substrate according to claim 4, wherein there are two first overlapping areas where orthographic projections of the adjacent two first power supply lines on the base substrate are overlapped with the orthographic projection of the pixel opening of the corresponding second sub-pixel on the base substrate, and there is one second overlapping area where an orthographic projection of the one data signal line on the base substrate is overlapped with the orthographic projection of the pixel opening of the corresponding second sub-pixel on the base substrate, wherein in the first direction, the two first overlapping areas are located on both sides of the one second overlapping area, and the two first overlapping areas are symmetrical with respect to the one second overlapping area.

6. The display substrate according to claim 4, wherein the conductive layer nearest to the pixel definition layer in the drive circuit layer is a second source drain metal layer, there is a first overlapping area where the orthographic projection of the pixel opening of the first sub-pixel on the base substrate is overlapped with orthographic projections of at least part of signal lines in the second source drain metal layer on the base substrate, there is a second overlapping area where the orthographic projection of the pixel opening of the second sub-pixel on the base substrate is overlapped with the orthographic projections of at least part of signal lines in the second source drain metal layer on the base substrate, and there is a third overlapping area where the orthographic projection of the pixel opening of the third sub-pixel on the base substrate is overlapped with the orthographic projections of at least part of signal lines in the second source drain metal layer on the base substrate, wherein areas of both the first overlapping area and the second overlapping area are greater than an area of the third overlapping area.

7. The display substrate according to claim 6, wherein an orthographic projection of the first overlapping area on the base substrate is symmetrical with respect to an orthographic projection of a midline of the pixel opening of the first sub-pixel extending in at least one of the first direction and the second direction on the base substrate; an orthographic projection of the second overlapping area on the base substrate is symmetrical with respect to an orthographic projection of a midline of the pixel opening of the second sub-pixel extending in at least one of the first direction and the second direction on the base substrate; an orthographic projection of the third overlapping area on the base substrate is symmetrical with respect to an orthographic projection of a midline of the pixel opening of the third sub-pixel extending in at least one of the first direction and the second direction on the base substrate.

8-9. (canceled)

10. The display substrate according to claim 1, wherein the drive circuit layer comprises a plurality of pixel drive circuits, at least part of the sub-pixels comprise the pixel drive circuits, and at least part of the pixel circuits comprise: at least one of first type transistors, at least one of second type transistors; the drive circuit layer comprises at least a first semiconductor layer, a first conductive layer, a second conductive layer, a second semiconductor layer, and a third conductive layer sequentially disposed on the base substrate, wherein:
the first semiconductor layer comprises at least: an active layer of the first type transistor in the pixel drive circuit; the first conductive layer comprises at least: a gate electrode of the first type transistor; the second conductive layer comprises at least: a bottom gate of the second type transistor; the second semiconductor layer comprises at least: an active layer of the second type transistor; the third conductive layer comprises at least: a top gate of the second type transistor.

11. The display substrate according to claim 10, wherein the drive circuit layer further comprises a fourth conductive layer on a side of the third conductive layer away from the base substrate in the direction perpendicular to the plane on which the display substrate located, and the fourth conductive layer comprises a plurality of second initial signal lines and a plurality of rows of second initial signal connection lines;
the pixel drive circuits of the plurality of sub-pixels are formed in a plurality of rows, the plurality of second initial signal lines are respectively electrically connected with the plurality of rows of the pixel drive circuits, and in a direction parallel to the plane on which the display substrate is located, the plurality of second initial signal lines extend in a first direction and are arranged at intervals in a second direction, wherein the first direction intersects with the second direction;
each row of the second initial signal connection lines comprises a plurality of the second initial signal connection lines extending in the second direction and arranged at intervals in the first direction, and in the second direction, each row of the second initial signal connection lines is located between two adjacent second initial signal lines, and both ends of the plurality of the second initial signal connection lines in each row of the second initial signal connection lines are respectively connected with the two adjacent second initial signal lines.

12. The display substrate according to claim 11, wherein the drive circuit layer further comprises a fifth conductive layer on a side of the fourth conductive layer away from the base substrate in the direction perpendicular to the plane on which the display substrate located, and the fifth conductive layer comprises a plurality of second power supply lines, and the second conductive layer further comprises a plurality of second power supply connection lines;
in the direction parallel to the plane on which the display substrate is located, the plurality of second power supply lines extend in the second direction and are arranged at intervals in the first direction, the plurality of second power supply connection lines extend in the first direction and are arranged at intervals in the second direction, and the plurality of second power supply lines and the plurality of second power supply connection lines are electrically connected through vias to form a grid-like structure.

13. The display substrate according to claim 12, wherein in the direction parallel to the plane on which the display substrate is located, the display substrate comprises a first display region, a second display region and a connection region, the first display region and the second display region are connected through the connection region, the second display region at least partially surrounds the first display region, and the pixel drive circuits of the plurality of sub-pixels are located in the first display region and the second display region and are formed in a plurality of columns;
the third conductive layer further comprises a plurality of second data signal connection lines, and the fifth conductive layer further comprises a plurality of first data signal lines and a plurality of second data signal lines; the plurality of first data signal lines are respectively electrically connected with a plurality of columns of pixel drive circuits located in the first display region, and the plurality of second data signal lines are electrically connected with a plurality of columns of pixel drive circuits located in the second display region; the plurality of second data signal connection lines are located in the second display region, and are respectively electrically connected with the plurality of columns of pixel drive circuits located in the second display region.

14. (canceled)

15. A display substrate comprising a first display region, a second display region, a bonding region and a connection region, wherein the first display region is connected with the second display region through the connection region, the second display region at least partially surrounds the first display region, and the bonding region is located on a side of the first display region in a direction parallel to a plane on which the display substrate is located;
the second display region is provided with a plurality of second data signal lines and a plurality of second data signal connection lines; one ends of the plurality of second data signal connection lines are respectively electrically connected with the plurality of second data signal lines, and the other ends are electrically connected with elements disposed in the bonding region.

16. The display substrate according to claim 15, wherein the second display region is provided with a plurality of pixel units, the plurality of pixel units forming a plurality of second pixel unit rows and a plurality of second pixel unit columns, and the plurality of second pixel unit columns are arranged sequentially in a direction from the first display region to the second display region, and distances between two adjacent second pixel unit rows are sequentially increased from a first one of second pixel unit columns to a last one of second pixel unit columns.

17. (canceled)

18. The display substrate according to claim 16, wherein the bonding region and the connection region are located on two opposite sides of the first display region in the direction parallel to the plane on which the display substrate is located, and the elements disposed in the bonding region comprises a driver chip, one ends of the plurality of second data signal connection lines being electrically connected with the driver chip.

19. The display substrate according to claim 18, further comprising a first outer bezel, wherein the first outer bezel is disposed on a periphery of the first display region, the first outer bezel comprises the connection region and the bonding region, the first outer bezel provided with a plurality of second data signal adapter lines, and the second data signal adapter lines and the second data signal connection lines are located in different conductive layers;
the second data signal connection lines extend from the second display region to the connection region, the plurality of second data signal adapter lines extend from the connection region along the first outer bezel to the bonding region, one ends being electrically connected with the plurality of second data signal connection lines located in the connection region, and the other ends being electrically connected with the driver chip.

20. The display substrate according to claim 19, further comprising a second outer bezel region and a second inner bezel region, wherein the second inner bezel region and the second outer bezel region are located on both sides of the second display region in a direction from the first display region to the second display region.

21. The display substrate according to claim 20, wherein the second inner bezel region is connected to the first outer bezel region through the connection region, and the first outer bezel region and the second inner bezel region are provided with a second power supply signal supply line, wherein the second power supply signal supply line is electrically connected to the driver chip, and extends to the second inner bezel region via the first outer bezel region.

22. The display substrate according to claim 21, further comprising a cathode layer, the second display region comprises a second power supply connection line electrically connected with a second power supply signal supply line in the second inner bezel region, and the second outer bezel region comprises a second power supply lap line overlapped with the cathode layer and the second power supply connection line, wherein the second power supply lap line is electrically connected with the second power supply connection line and the cathode layer through a via.

23. (canceled)

24. The display substrate according to claim 20, wherein in a direction from the second display region to the second inner bezel region, the second inner bezel region sequentially comprises: a first type gate drive circuit and a first type drive signal line, an initial signal line, a first power supply signal supply line, and a second power supply signal supply line electrically connected with the first type gate drive circuit;
in a direction from the second display region to the second outer bezel region, the second outer bezel region sequentially comprises: a second type gate drive circuit and a second type drive signal line and a second power supply lap line electrically connected with the second type gate drive circuit, wherein the second type drive signal line is electrically connected with the driver chip via the second outer bezel region, the second inner bezel region, and the first outer bezel region.

25. The display substrate according to claim 24, wherein the connection region is provided with an initial signal adapter electrode disposed in a different layer from the initial signal line, a first power supply adapter electrode disposed in a different layer from the first power supply signal supply line, a second power supply adapter electrode disposed in a different layer from or in a same layer as the second power supply signal supply line, and a drive signal adapter electrode disposed in a different layer from the first type drive signal line;
in a direction from the first display region to the first outer bezel region, the first outer bezel region sequentially comprises: a first power supply signal supply line, an initial signal line, a first type drive signal line, and a second power supply signal supply line;
the first power supply signal supply line located in the first outer bezel region is electrically connected with the first power supply signal supply line located in the second inner bezel region through the first power supply adapter electrode; the initial signal line located in the first outer bezel region is electrically connected with the initial signal line located in the second inner bezel region through the initial signal adapter electrode; the first type drive signal line located in the first outer bezel region is electrically connected with the first type drive signal line through the drive signal adapter electrode; and the second power supply signal supply line located in the first outer bezel region is electrically connected with the second power supply signal supply line located in the second inner bezel region through the second power supply adapter electrode.

26-28. (canceled)
